(19) United States
(12) Patent Application Publication
(10) Pub. No.: US 2016/0276265 A1
(43) Pub. Date: Sep. 22, 2016

(54) SEMICONDUCTOR DEVICE

(71) Applicant: RENESAS ELECTRONICS CORPORATION, Kanagawa (JP)

(72) Inventor: Masaru IWABUCHI, Kanagawa (JP)

(73) Assignee: RENESAS ELECTRONICS CORPORATION, Kanagawa (JP)

(21) Appl. No.: 14/381,487

(22) PCT Filed: Dec. 6, 2013
(86) PCT No.: PCT/JP2013/082850

§ 371 Date: Aug. 27, 2014

(51) Int. Cl. H01L 23/522; H01L 27/02; H01L 49/02; H01L 23/528; H01L 29/94

(52) U.S. Cl. CPC H01L 23/5223; H01L 23/5286; H01L 29/94; H01L 28/60; H01L 27/0248

(57) ABSTRACT

A semiconductor device which can achieve a reduction of EMI noises is provided. For example, a first region which is used for forming a core circuit block CRBK, a first power-source voltage line (LNVD1) in the first region, a first power-source voltage generating circuit (VREG), a first power source pad (PDvcl) outside the first region, a second power-source voltage line LNVD2 which connects the LNVD1 and the PDvcl, and an on-chip capacitor CC are provided. The PDvcl is connected to an external capacitor. The CC includes an upper electrode UPN which has a partial section of the LNVD2 and a lower electrode LWN to which a reference power-source voltage VSS is supplied. A first power source voltage (VDD) on the LNVD1 is applied to the PDvcl through the UPN.

### TECHNICAL FIELD

The present invention relates to a semiconductor device, and for example relates to a technique which is effectively applied to a semiconductor device such as a microcomputer.

### BACKGROUND

For example, Patent Document 1 discloses a technique of reducing power source noises by using a decoupling capacitor which is configured such that a power-source potential line and a ground potential line are disposed in the vicinity of each unit cell and an insulating film is disposed between the power-source potential line and the ground potential line. Patent Document 2 discloses a configuration in which an outer peripheral power source line connected to a power-source terminal pad and an inner-circuit power source line (for the power source potential and the ground potential) provided between an inner circuit and an outer peripheral power source line are provided, and the outer peripheral power source line and the inner-circuit power source line are connected only at one place. The inner-circuit power source line (for the power source potential) and the power source line (for the ground potential) are disposed adjacent to each other for forming an RC filter, so that EMI noises generated by the inner circuit are attenuated.

Patent Document 3 discloses a configuration in which an inner-circuit power source terminal and a common ground terminal to which the power source voltage and the ground voltage are applied from outside respectively, a protection circuit which is inserted on the line from the inner-circuit power source terminal, and a bypass capacitor which is connected between a line from the inner-circuit power source terminal and a line from the common ground terminal. There is a description that the bypass capacitor can be configured by a gate capacitor of a MOS transistor or an interline capacitor.

### PRIOR ART DOCUMENTS

### Patent Documents

Patent Document 1: Japanese Patent Application Laid-Open Publication No. 2008-300765
Patent Document 2: Japanese Patent Application Laid-Open Publication No. 2009-283792
Patent Document 3: Japanese Patent Application Laid-Open Publication No. 2011-216592

### SUMMARY

### Problems to be Solved by the Invention

In recent years, semiconductor devices represented by a microcomputer and the like are increased in speed and decreased in an internal power source voltage as the process has been scaled down, so that countermeasures against power source noises and electromagnetic compatibility (EMC) noises gradually rise in importance. In order to easily satisfy the decrease in the internal power source voltage, it is favorable that a power-source voltage regulator circuit is provided to generate a predetermined internal power source voltage in the semiconductor device. In the semiconductor device with such a power-source voltage regulator circuit built therein, for example, in a case where a rush current is generated in a circuit among inner circuits (hereinafter, also referred to as core circuits), the power source noise is generated in the internal power source voltage, and may cause a malfunction in another circuit in the core circuits.

In order to achieve stability in the internal power source voltage, there is considered a scheme in which the internal power source voltage is extracted to the outside of the semiconductor device and a bypass capacitor is connected to the extracted place. However, the inventor has studied about the above-described scheme, and as a result, they have found out that, when the scheme is used, it causes such a problem in that EMC noise (specifically, the EMI noise (emission noise)) is generated in the power source terminal at the extracted place. Making an explanation in detail, it is desirable that a power source voltage route between the core circuit and the power source terminal be made small in impedance in order to make the external bypass capacitor efficiently operate. On the contrary, as the impedance is reduced, the power source noise generated in the core circuit is easily transferred to the power source terminal, and the emission noise in the power source terminal may be increased.

In such a circumstance, techniques of Patent Documents 1 to 3 are known. In all these techniques, the scheme of leading out the internal power source voltage to the power source terminal as described above is not used, and the power source terminal serves as a terminal of a power-source voltage source. Therefore, though the premise is not the same, even in a case where the same techniques as those of Patent Documents 1 to 3 are applied to the scheme, there is a concern that the following problems may occur.

For example, Patent Document 1 discloses a technique in which the power source noise is reduced using the power-source potential line and the ground potential line provided in the core circuit of the semiconductor device. However, it is difficult to sufficiently reduce the power source noise generated in the core circuit only by the interline capacitance in such a core circuit. As a countermeasure, there is consideration for using the scheme of leading out the internal power source voltage in the core circuit to the power source terminal as described above, but in this case it causes a problem of emission noise in the power source terminal after all.

Further, Patent Document 2 discloses a technique in which the entire section of the power source line connecting the power source terminal (to which external power source is supplied) and the core circuit is designed to serve as an RC filter. In a case where the technique is used, a long power source line between the power source terminal and the core circuit is required for securing a sufficient property of the RC filter. Then, the EMI noise (emission noise) from the core circuit toward the power source terminal can be reduced, but on the contrary, there occurs a problem about how to reduce the power source noise generated in the core circuit. Supposing, in a case where an external bypass capacitor is connected to the power source terminal, the bypass capacitor has trouble in efficient operation due to the long power source line between the power source terminal and the core circuit.

Patent Document 3 discloses a configuration in which the bypass capacitor is connected on the power-source voltage route between the power source terminal (to which external power source is supplied) and the core circuit. However, in a case where the bypass capacitor is formed using a gate capacitance of a general MOS transistor or an interline capacitance, the operation as the bypass capacitor is not sufficiently obtained, and the power source noise generated in the core circuit is not possible to be sufficiently reduced in some cases. As a result, there is caused a problem of the EMI noise (emission noise) in the power source terminal after all.

The embodiments described hereinafter are made in consideration of the foregoing. The above and other preferred aims and novel characteristics of the present invention will be apparent from the description of the present specification and the accompanying drawings.

### Means for Solving the Problems

A semiconductor device of one embodiment is formed of one semiconductor substrate. The semiconductor device a first region for forming a core circuit block executing a predetermined process; a first power-source voltage line disposed in the first region; a first power source pad disposed on the outside of the first region; and a second power-source voltage line for connecting the first power-source voltage line and the first power source pad; and an on-chip capacitor. The first power-source voltage line supplies a first power source voltage to the core circuit block. The first power-source voltage generating circuit generates the first power source voltage using a power source voltage from outside. The first power source pad is for connecting an external capacitor. The on-chip capacitor includes a first electrode having a partial section of the second power-source voltage line and a second electrode for supplying a reference power source voltage. The first power source voltage on the first power-source voltage line is applied to the first power source pad through the first electrode.

### Effects of the Invention

According to the embodiment, it is possible to achieve a reduction in the EMI noise (emission noise).

### BRIEF DESCRIPTION OF THE DRAWINGS

FIG. 1 is a plan view schematically illustrating an exemplary configuration of an entire semiconductor device according to a first embodiment of the invention;

FIG. 2 is a plan view schematically illustrating an exemplary configuration of a wiring board on which the semiconductor device of FIG. 1 is mounted;

FIG. 3 is a diagram schematically illustrating an exemplary configuration of main parts of the semiconductor device of FIG. 1;

FIG. 4 is a diagram for describing an example of effect of the semiconductor device of FIG. 3;

FIG. 5A is a circuit symbol schematically illustrating an on-chip capacitor in FIG. 3;

FIG. 5B is a circuit symbol as a comparative example of FIG. 5A;

FIG. 6 is a circuit diagram illustrating an example of an equivalent circuit including a power-source voltage regulator circuit and the peripheral circuits in the semiconductor device of FIG. 1;

FIG. 7 is a circuit block diagram illustrating an example of an actual configuration of the peripheral circuits of the power-source voltage regulator circuit in the semiconductor device of FIG. 1;

FIG. 8 is a plan view schematically illustrating an example of arrangement of the on-chip capacitor in a semiconductor chip of the semiconductor device of FIG. 3;

FIG. 9 is a diagram schematically illustrating various structures of the on-chip capacitor in the semiconductor device of FIG. 3;

FIG. 10A is a plan view schematically illustrating an example of a layout configuration of an on-chip capacitor of a semiconductor device according to a second embodiment of the invention;

FIG. 10B is a cross-sectional view illustrating an exemplary structure taken along the line A-A′ of FIG. 10A;

FIG. 11 is a plan view illustrating an exemplary configuration of a detailed layout of the peripheral circuits of the on-chip capacitor of FIG. 8, in which the on-chip capacitor of FIGS. 10A and 10B including the peripheral circuits are illustrated in more detail;

FIG. 12 is a circuit diagram illustrating an example of a detailed configuration of a protection circuit for preventing electrostatic discharge damage of FIG. 11;

FIG. 13 is a three-dimensional view schematically illustrating an exemplary configuration of part of the on-chip capacitor of FIGS. 10A and 10B;

FIG. 14 is a cross-sectional view illustrating an exemplary structure of the on-chip capacitor taken along the line B-B′ of FIG. 11;

FIG. 15 is a plan view illustrating an exemplary configuration of a detailed layout of the peripheral circuits of the on-chip capacitor of FIG. 8 in a semiconductor device according to a third embodiment of the invention;

FIG. 16A is a cross-sectional view illustrating an exemplary structure of a unit on-chip capacitor taken along the line C-C′ of FIG. 15;

FIG. 16B is a cross-sectional view illustrating an exemplary structure of the unit on-chip capacitor taken along the line D-D′ of FIG. 15;

FIG. 17A is a diagram illustrating an example of the simplified cross-sectional structure of FIG. 16A and the equivalent circuit thereof;

FIG. 17B is a diagram illustrating an example of a cross-sectional structure as a comparative example of FIG. 17A and the equivalent circuit thereof;

FIG. 18 is a cross-sectional view illustrating an exemplary structure of a metal gate which is used as a gate line of the on-chip capacitor of FIGS. 16A and 16B;

FIGS. 19A, 19B, and 19C are diagrams for describing an exemplary effect of an external capacitor which is connected to an external terminal used for an internal power source voltage in the semiconductor device of FIGS. 1 and 2; and

FIG. 20 is a diagram for describing an example of a problem in a case where the external capacitor connected to the external terminal used for the internal power source voltage is employed in the semiconductor device of FIGS. 1 and 2.

### DETAILED DESCRIPTION

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof. Also, in the embodiments described below, when referring to the number of elements (including number of pieces, values, amount, range, and the like), the number of the elements is not limited to a specific number unless otherwise stated or except the case where the number is apparently limited to a specific number in principle. The number larger or smaller than the specified number is also applicable.

Further, in the embodiments described below, it goes without saying that the components (including element steps) are not always indispensable unless otherwise stated or except the case where the components are apparently indispensable in principle. Similarly, in the embodiments described below, when the shape of the components, positional relation thereof, and the like are mentioned, the substantially approximate and similar shapes and the like are included therein unless otherwise stated or except the case where it is conceivable that they are apparently excluded in principle. The same goes for the numerical value and the range described above.

Moreover, while the circuit elements forming respective function blocks of embodiments are not particularly limited, by integrated circuit technology for known CMOS (complimentary MOS transistor) etc., they are formed on a semiconductor substrate of, for example, single crystal silicon. Hereinafter, embodiments of the present invention will be described in detail with reference to the accompanying drawings. Note that components having the same function are denoted by the same reference symbols throughout the drawings for describing the embodiment, and the repetitive description thereof will be omitted.

### First Embodiment

### Schematic Configuration of Entire Semiconductor Device

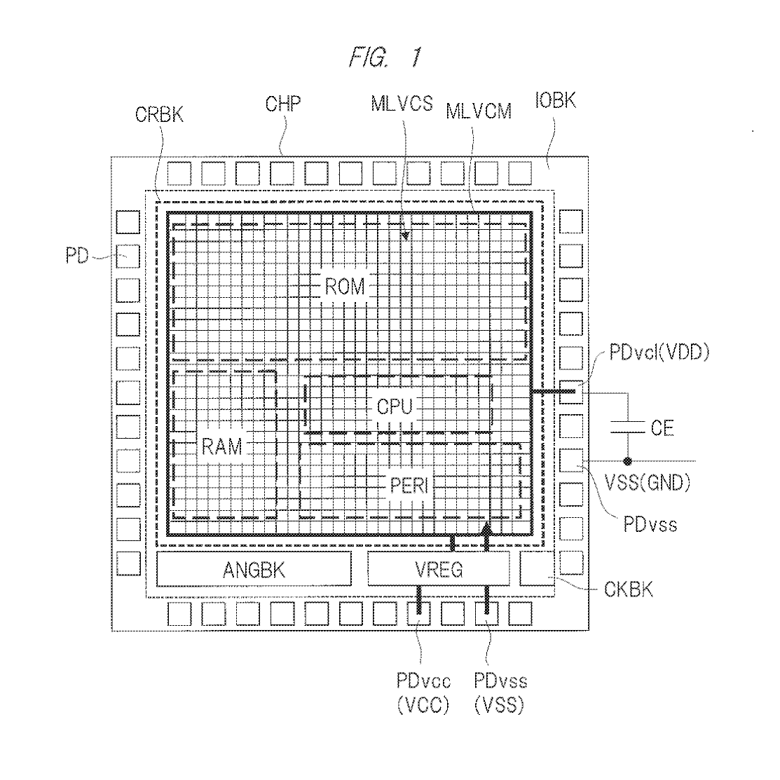

FIG. 1 is a plan view schematically illustrating an exemplary configuration of an entire semiconductor device according to the first embodiment of the invention. As an example of the semiconductor device, FIG. 1 illustrates a semiconductor chip CHP which includes one semiconductor substrate. Examples of the CHP include a microcomputer and the like. The CHP includes an external input/output block (IO block) IOBK in an outer peripheral portion, and includes therein a core circuit block CRBK, an analog circuit block ANGBK, a power-source voltage regulator circuit VREG, and a clock generating circuit block CKBK. In the IOBK, a plurality of pads PD are disposed. In the PDs, a pad PDvcc for a power source voltage VCC, a pad PDvss for a reference power source voltage VSS (a ground power source voltage GND), and a pad PDvcl for an internal power source voltage VDD are included.

Examples of the analog circuit block ANGBK include various types of analog circuits representing an analog-to-digital conversion circuit and a digital-to-analog conversion circuit. Although not illustrated, for example, the ANGBK is directly supplied with power from the pad PD. The power-source voltage regulator circuit VREG receives the power source voltage VCC from the pad PDvcc and the reference power source voltage VSS from the pad PDvss, and generates the internal power source voltage VDD. The VCC is such as 2.7 V to 5.5 V, and the VDD is such as 1.1 V to 1.8 V, but not limited thereto. The clock generating circuit block CKBK, for example, includes a crystal oscillation circuit, a phase locked loop (PLL) circuit and the like, and generates various types of clock signals which are used in the semiconductor chip CHP.

The core circuit block CRBK is a circuit block which executes a predetermined process according to the internal power source voltage VDD supplied from the power-source voltage regulator circuit VREG, and to which a miniaturization process is applied. The CRBK includes a nonvolatile memory ROM such as a flash memory, a volatile memory RAM such as a static random access memory (SRAM), a processor circuit CPU, and various types of peripheral circuits PERI such as a timer circuit and a serial communication circuit. Further, the CRBK includes a main power-source voltage line MLVCM which is disposed along the outer peripheral portion and a sub power-source voltage line MLVCS which is disposed in a mesh shape branched from the MLVCM. The MLVCS is generally formed using lines thinner than those of the MLVCM.

The main power-source voltage line MLVCM is connected to the output of the power-source voltage regulator circuit VREG, and the internal power-source voltage VDD is supplied thereto. The respective circuits in the CRBK are appropriately connected to the MLVCS, and supplies the VDD through the MLVCM and the MLVCS from the VREG. Further, the MLVCM is connected to the pad PDvcl for the internal power source voltage VDD. The PDvcl is a pad serving to stabilize the VDD, and an external capacitor CE to be provided on the outside of the semiconductor chip CHP is connected between the PDvcl and the pad PDvss for the reference power source voltage VSS. The CE, such as, is a laminated ceramic capacitor having a capacitance value in a range of 0.1 μF to 1 μF. In addition, although not illustrated, similarly to the power-source voltage lines (MLVCM and MLVCS) for the VDD, the CHP practically includes a reference power-source voltage line for the VSS including a main reference power-source voltage line and a sub reference power-source voltage line. The main reference power-source voltage line is connected to the PDvss.

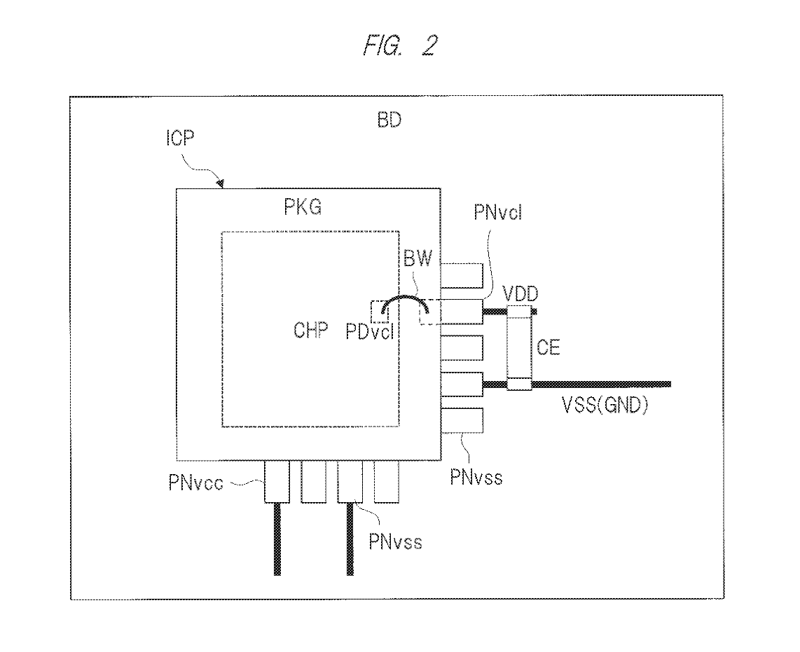

FIG. 2 is a plan view schematically illustrating an exemplary configuration of a wiring board on which the semiconductor device of FIG. 1 is mounted. An IC package ICP as an example of the semiconductor device is built on a wiring board BD illustrated in FIG. 2. The ICP is formed by sealing the semiconductor chip CHP of FIG. 1 with a package (for example, resin) PKG. The ICP includes external terminals (for example, leads) PNvcc, PNvss, and PNvcl which are connected to the pads PDvcc, PDvss, and PDvcl, respectively. Herein, as a representative, a connection point between the pad (a first power source pad) PDvcl and the external terminal (a first power source terminal) PNvcl is illustrated, and the PDvcl is connected to the PNvcl through a bonding wire BW. In addition to the respective patterns connected to the PNvcc, the PNvss, and the PNvcl, the BD includes an external capacitor CE which is built between the line pattern of the PNvcl and the line pattern of the PNvss.

For example, as the process in the core circuit block CRBK is miniaturized, the internal power source voltage VDD is lowered. In order to easily meet the voltage reduction, as illustrated in FIGS. 1 and 2, it is favorable that the power-source voltage regulator circuit VREG is provided in the semiconductor chip CHP (the IC package ICP). However, in this case, since power source noises are generated from the VREG, there is a need to reduce the noises. Therefore, herein, the VDD is extracted through the pad PDvcl and the external terminal PNvcl to the external, and connected to the external capacitor CE which operates as a bypass capacitor, so that the power source noises are reduced.

<<Effects and Problems of External Capacitor>>

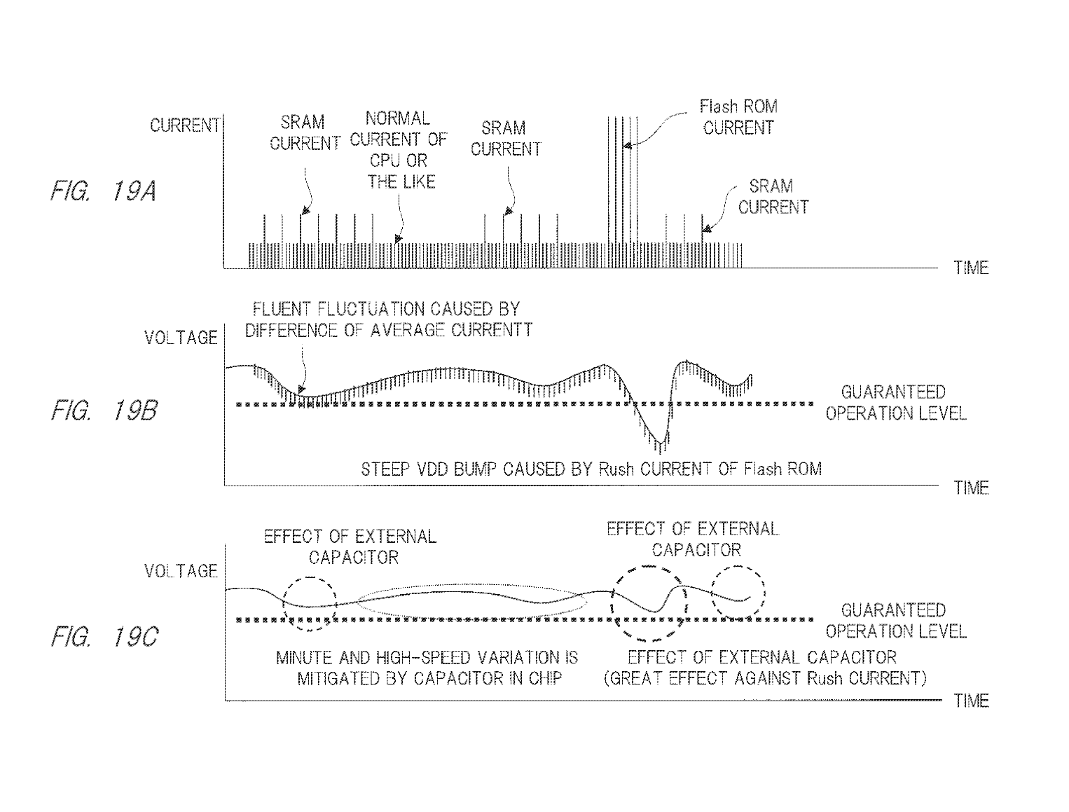

FIGS. 19A, 19B, and 19C are diagrams for describing an exemplary effect of an external capacitor which is connected to an external terminal used for an internal power source voltage in the semiconductor device of FIGS. 1 and 2. As illustrated in FIG. 19A, the current consumption of the core circuit block CRBK slightly varies at a high frequency according to the operations of the respective circuits therein, and greatly varies at a low frequency according to switching between the operation and the non-operation of the respective circuits. Accordingly, as illustrated in FIG. 19B, the internal power source voltage VDD applied on the power source lines in the CRBK (the main power-source voltage line MLVCM and the sub power-source voltage line MLVCS) has a small variation component at the high frequency, and a large variation component at the low frequency.

For example, as illustrated in FIG. 19A, a large rush current flows at the moment when the flash memory (ROM) and the like start a high speed operation from the non-operation, and accordingly the VDD is steeply damped as illustrated in FIG. 19B. The steep damping in the VDD may cause malfunctions against the respective circuits in the core circuit block CRBK. On the contrary, although not illustrated, a parasitic inductance component or the like may cause a steep rising in the VDD as the current varies in a steep manner. The steep rising in the VDD affects the reliability of the respective circuits, and may cause an increase in current consumption.

The small variation component at the high frequency illustrated in FIG. 19B is reduced to some degree by a parasitic capacitance in the core circuit block CRBK and capacitors actively formed in the CRBK. Further, in a case where the level is low, the large variation component at the low frequency is reduced to some degree by a feedback property of the power-source voltage regulator circuit VREG. However, it cannot be said that the reduction degree is sufficient, and furthermore it is difficult to suppress the steep damping/rising in the VDD as described above only by the capacitance in the CRBK, the capacitors, and the feedback property of the VREG. Further, such a problem becomes remarkable as the operating speed of the semiconductor device is increased.

Therefore, it is favorable that the external capacitor CE illustrated in FIGS. 1 and 2 is employed. Under conditions that the CE operates efficiently, as illustrated in FIG. 19C, the small variation component at the high frequency and the large variation component at the low frequency can be both reduced sufficiently. In particular, the steep damping/rising in the VDD can be effectively suppressed. However, such an effect can be obtained on an assumption that the CE efficiently operates as the bypass capacitor.

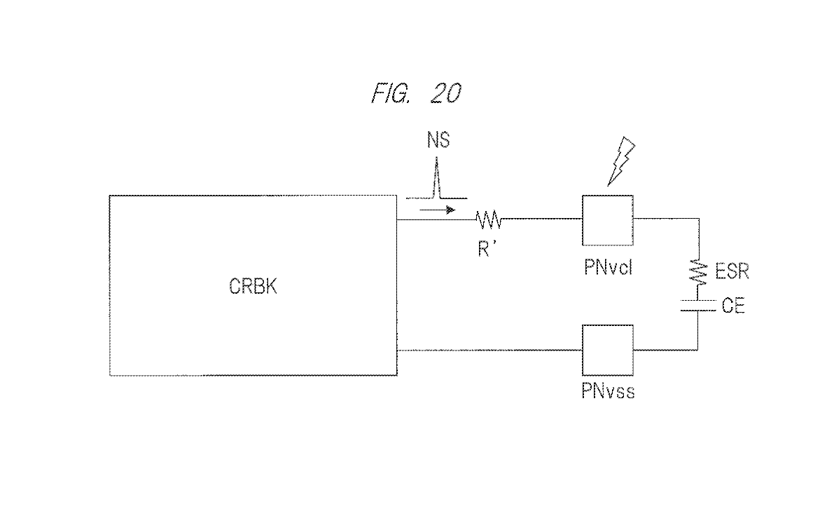

FIG. 20 is a diagram for describing an example of a problem in a case where the external capacitor connected to the external terminal used for the internal power source voltage is employed in the semiconductor device of FIGS. 1 and 2. As described above, in order to make the external capacitor CE efficiently operate as the bypass capacitor, in FIG. 20, it is desirable that impedance (herein, simply denoted by resistance R′) between the core circuit block CRBK and the external terminal PNvcl be set to a value as low as possible. On the contrary, the power source noise NS generated in the CRBK becomes easily transferred to the PNvcl as the impedance (R′) is lowered. As a result, an EMI noise (emission noise) generated from the PNvcl is also easily increased. Making a simple explanation, as a ratio of the impedance (R′) is lowered with respect to an equivalent series resistance (ESR) and the like of the CE, the EMI noise (emission noise) may be increased.

<<Schematic Configuration of Semiconductor Device (Main Parts of the Embodiment)>>

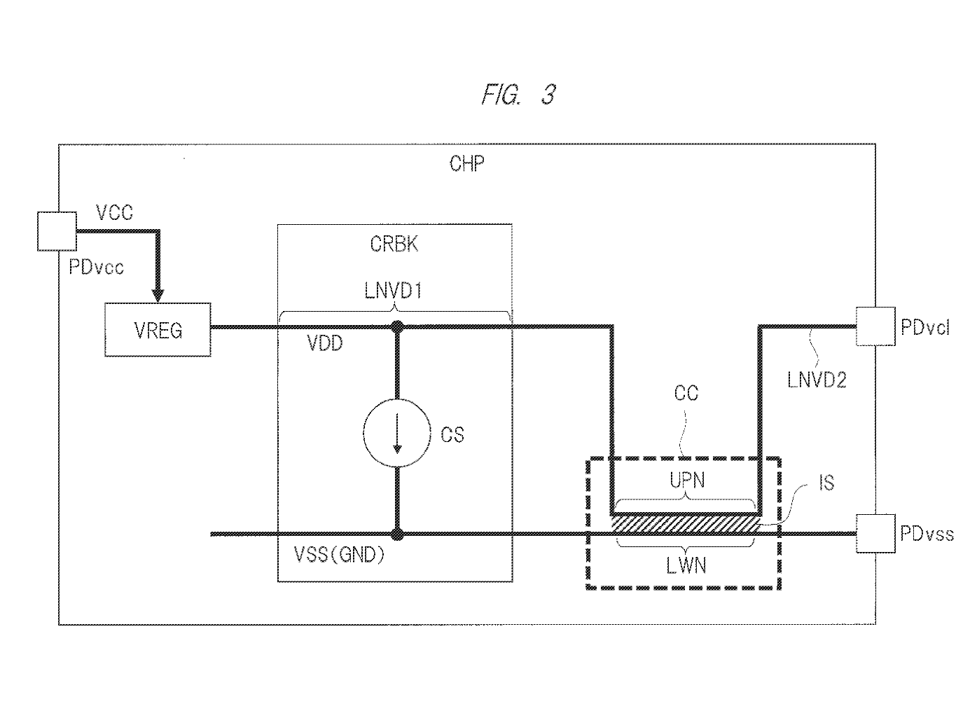

In order to solve the problem as described above with reference to FIG. 20, it is favorable that an exemplary configuration illustrated in FIG. 3 is employed. FIG. 3 is a diagram schematically illustrating an exemplary configuration of main parts of the semiconductor device of FIG. 1. The semiconductor chip CHP illustrated in FIG. 3 includes an on-chip capacitor CC in addition to the power-source voltage regulator circuit (a first power-source voltage generating circuit) VREG and the core circuit block CRBK. The CRBK includes a power-source voltage line (a first power-source voltage line) LNVD1 which is disposed in the CRBK and supplies the internal power source voltage (a first power source voltage) VDD to the respective circuits in the CRBK. The power-source voltage line (the first power-source voltage line) LNVD1 corresponds to the main power-source voltage line MLVCM and the sub power-source voltage line MLVCS in FIG. 1.

The power-source voltage regulator circuit (a first power-source voltage generating circuit) VREG generates the internal power source voltage (the first power source voltage) VDD using the power source voltage VCC supplied to the pad PDvcc from outside. The pad (the first power source pad) PDvcl is a pad which is disposed on the outside of the core circuit block CRBK and is connected to the external capacitor CE as described above. The pad (the first power source pad) PDvcl and the power-source voltage line (the first power-source voltage line) LNVD1 are connected to each other by a power-source voltage line (a second power-source voltage line) LNVD2 which is disposed on the outside of the CRBK. The on-chip capacitor CC includes a lower electrode (a second electrode) LWN to which the reference power source voltage VSS (the ground power source voltage GND) is supplied and an upper electrode (a first electrode) UPN. An insulating film IS is provided between the LWN and the UPN. Herein, the CC uses a partial section of the LNVD2 as the UPN.

The internal power source voltage (the first power source voltage) VDD generated by the power-source voltage regulator circuit (the first power-source voltage generating circuit) VREG is supplied to the power-source voltage line (the first power-source voltage line) LNVD1 of the core circuit block CRBK, and the VDD on the LNVD1 is applied to the pad (the first power source pad) PDvcl through the upper electrode (the first electrode) UPN of the on-chip capacitor CC. The CRBK can be represented as a current source CS which is connected between the LNVD1 and the line for the reference power source voltage VSS. The current value of the CS is frequently changed according to processing details of the CRBK. Since the LNVD1 and the VSS line actually have an equivalent series resistance component or the like therebetween, the power source noise is generated in the VDD and the VSS according to a variation in current value of the CS.

<<Main Effects of Semiconductor Device (Main Parts of the Embodiment)>>

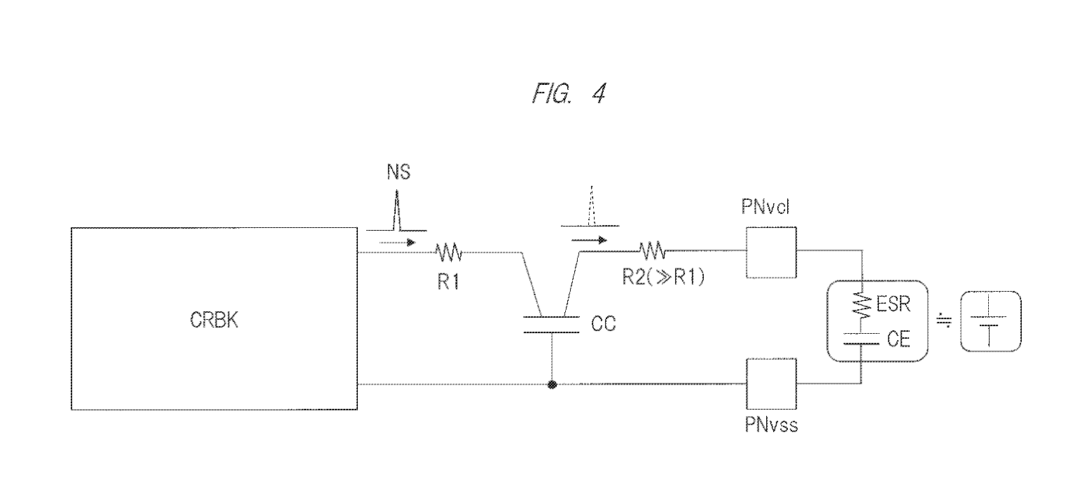

FIG. 4 is a diagram for describing an example of effect of the semiconductor device of FIG. 3. In FIG. 4, the core circuit block CRBK and the upper electrode of the on-chip capacitor CC are connected to each other with a predetermined impedance (herein, simply denoted by resistance R1) therebetween, and the upper electrode of the CC and the external terminal PNvcl are connected to each other with a predetermined impedance (herein, simply denoted by resistance R2) therebetween. Herein, the impedance (R1) is designed to be sufficiently low compared to the impedance (R2). In a practical design, since the impedance (R2) is at a high value from the beginning according to the bonding wire BW or the like of FIG. 2 for example, it is preferable that the impedance (R1) be designed to have a value as low as possible. As a result, since the CC efficiently operates as the bypass capacitor according to the low impedance (R1), the power source noise NS generated in the CRBK is significantly reduced in the upper electrode of the CC.

On the other hand, since the impedance (R1) is low, the external capacitor CE operates as the bypass capacitor to some degree, and in this case operates also as a secondary battery. The power source noise significantly reduced in the upper electrode of the on-chip capacitor CC is further reduced through the high impedance (R2), and transferred to the external terminal PNvcl to which the secondary battery (the bypass capacitor) is connected. As a result, it is possible to significantly reduce the EMI noise (emission noise) generated in the PNvcl. Further, in this case, the power source noise generated in the core circuit block CRBK can also be reduced by the on-chip capacitor CC and the external capacitor CE (in particular, the on-chip capacitor CC). Unlike the case of FIG. 20, the reduction of the power source noise and the reduction of the EMI noise (emission noise) can be compatible with each other.

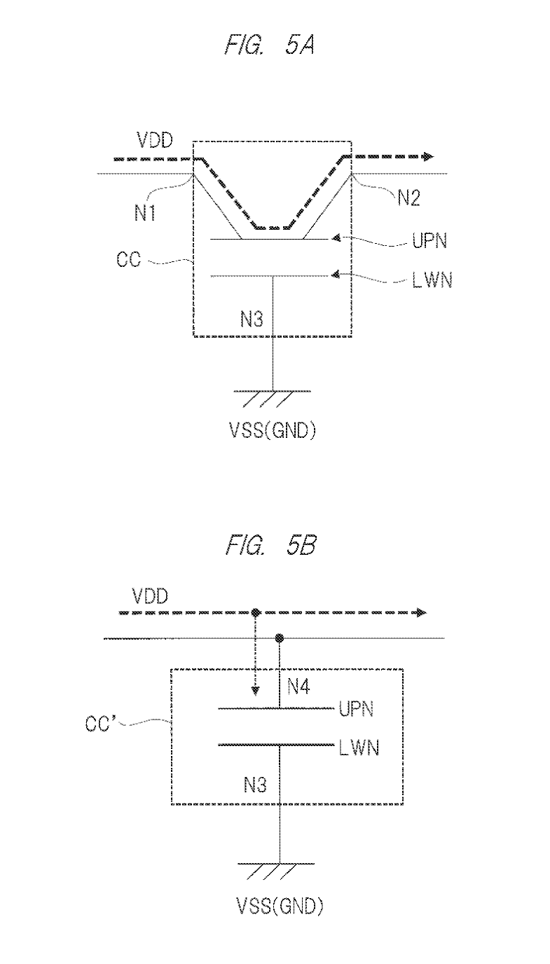

Furthermore, as in the following description, the reduction effect of the above-mentioned EMI noise (emission noise) and the reduction effect of the power source noise can be made increased by using the on-chip capacitor CC which uses the partial section of the power-source voltage line (the second power-source voltage line) LNVD2 as the upper electrode (the first electrode) UPN as described with reference to FIG. 3. FIG. 5A is a circuit symbol schematically illustrating an on-chip capacitor in FIG. 3, and FIG. 5B is a circuit symbol as a comparative example of FIG. 5A.

By using the on-chip capacitor CC having the structure of FIG. 3, the power source noise generated in the core circuit block CRBK is transferred to the pad PDvcl (the external terminal PNvcl) certainly through the upper electrode (the first electrode) UPN. This operation can be represented using the circuit symbol illustrated in FIG. 5A for example. The CC illustrated in FIG. 5A has three nodes N1 to N3, and for example, N3 is used for the reference power source voltage VSS (the ground power source voltage GND) and the internal power source voltage VDD input from the N1 is output from the N2. In this case, the UPN serves as the power-source voltage line of the VDD from the node N1 to the node N2, and also serves as the electrode of the capacitor.

On the contrary, an on-chip capacitor CC′ as a comparative example illustrated in FIG. 5B has two nodes N3 and N4, and is configured such that the node N3 is used for the reference power source voltage VSS (the ground power source voltage GND) and the node N4 is connected in parallel with the power-source voltage line of the internal power source voltage VDD. The circuit symbol of FIG. 5B, for example, corresponds to a general MOS transistor capacitor or the like. In other words, the general MOS transistor capacitor, for example, has a structure such that one end of a contact layer is connected to the node (N4) on a metal line and the other end of the contact layer is connected to a gate electrode.

In FIG. 5B, the node N4 includes a resistance component (not illustrated) to be exact. In that case, in the on-chip capacitor CC′ of FIG. 4B, the internal power source voltage VDD containing the power source noise directly passes the power-source voltage line having a low impedance, so that this situation may cause the CC′ not to efficiently operate as the bypass capacitor. In other words, there is a concern that an effective capacitance value working as the bypass capacitor becomes a part of the capacitance of the CC′. In order to make the CC′ efficiently operate, there is a need to further increase the capacitance of the CC′ (for example, a circuit region of the CC′ is made large).

On the other hand, when the on-chip capacitor CC of FIG. 5A is used, the internal power source voltage VDD containing the power source noise certainly passes through the upper electrode (the first electrode) UPN, so that the CC efficiently operates as the bypass capacitor. In other words, the capacitance value of the CC and the effective capacitance value working as the bypass capacitor become equal to each other. Therefore, with the use of the CC, for example, the same effect as that of the on-chip capacitor CC′ can be obtained using a capacitance value smaller than the capacitance value of the CC′. Further, in a case where the CC and the CC′ have the same capacitance value, the effective capacitance value working as the bypass capacitor can be made larger than that of the CC′ by using the CC. In other words, it is possible to achieve the on-chip capacitor which has a smaller region but operates more efficiently.

In addition, for example, the bypass capacitor has a function of reducing a high-frequency power source noise generated in the internal power source voltage VDD by bypassing the noise toward the reference power source voltage VSS using an impedance property (1/(Frequency×Capacitance value)) of the capacitor. In order to increase the effect working as the bypass capacitor, it is favorable to increase the capacitance value to some degree and to connect the electrode of a low-impedance bypass capacitor to a noise source.

<<Schematic Configuration of Peripheral Circuits of Power-Source Voltage Regulator Circuit>>

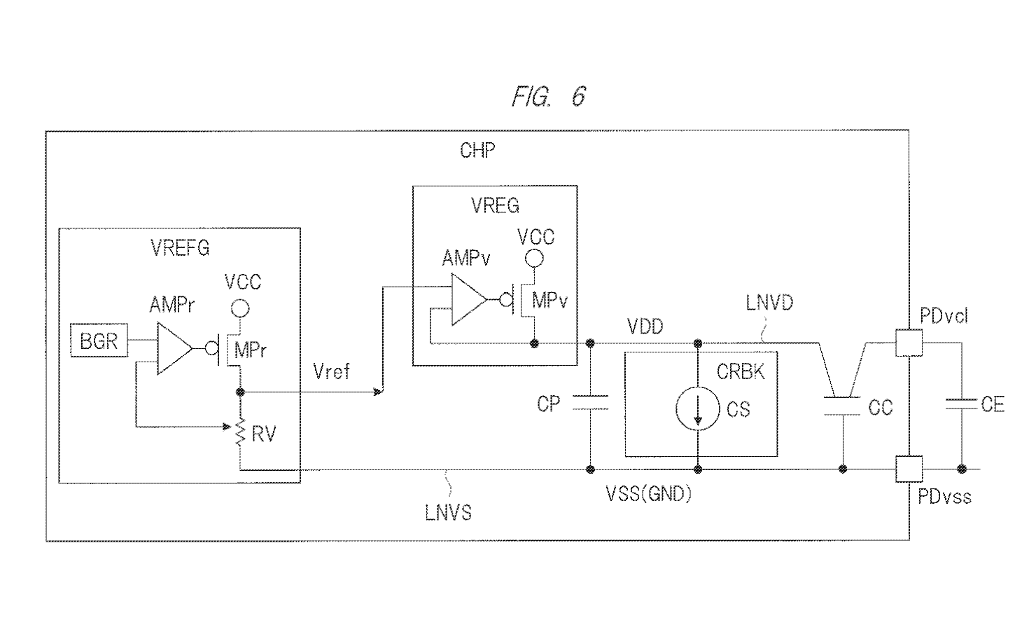

FIG. 6 is a circuit diagram illustrating an example of an equivalent circuit including a power-source voltage regulator circuit and the peripheral circuits in the semiconductor device of FIG. 1. The power-source voltage regulator circuit VREG illustrated in FIG. 6 is a linear regulator, and includes an amplifier circuit AMPv and a PMOS transistor MPv. The MPv is configured such that the power source voltage VCC is supplied to the source and the inner power source voltage VDD is output through the drain. The AMPv is configured such that a reference voltage Vref is applied to one of two inputs and the VDD (the drain of the MPv) is fed back to the other one of the two inputs so as to control the gate voltage of the MPv so that the VDD is matched with the Vref.

The reference voltage Vref is generated by a reference voltage generating circuit VREFG. The VREFG includes a bandgap reference circuit BGR, an amplifier circuit AMPr, a PMOS transistor MPr, and a variable resistor RV. The MPr is configured such that the power source voltage VCC is supplied to the source and the Vref is output from the drain. The RV functions as a so-called trimming resistor which performs a resistive voltage division between the drain voltage (Vref) of the MPr and the reference power source voltage VSS (the ground power source voltage GND) at a predetermined ratio, and corrects a variation or the like in manufacturing processes. The ratio of resistive voltage division, for example, is stored in the non-volatile memory ROM of FIG. 1 in advance. The AMPr is configured such that the output voltage of the BGR is applied to one of two inputs and the voltage at a resistive voltage division node in the RV is fed back to the other one of the two inputs so as to control the gate voltage of the MPr so that the voltage at the resistive voltage division node is matched with the output voltage of the BGR.

The internal power source voltage VDD generated by the power-source voltage regulator circuit VREG is supplied to the core circuit block CRBK through a power-source voltage line LNVD, and also applied to the pad PDvcl through the on-chip capacitor CC. Further, the reference power source voltage VSS (the ground power source voltage GND) is supplied from the pad PDvss, and the VSS (GND) is supplied to the respective parts inside the semiconductor chip CHP through a reference power-source voltage line LNVS. A capacitor CP is connected between the LNVD and the LNVS in addition to the on-chip capacitor CC.

The capacitor CP, for example, corresponds to a line capacitor between the mesh-shaped sub power-source voltage line MLVCS illustrated in FIG. 1 and a sub reference power-source voltage line (not illustrated), or a capacitor of a diffusion layer of each transistor included in the core circuit block CRBK, or the like. Further, in some cases, a capacitor actively formed in the CRBK is also included. As described with reference to FIG. 19, the power source noise having high frequencies and low frequencies can be reduced to some degree by such a CP, the external capacitor CE, and the feedback property of the power-source voltage regulator circuit VREG. However, for example, a capacitance value of only about nF (nanofarad) order is obtained only by the CP, so that the capacitance value may be insufficient. Further, regarding the CE, there may cause the problem as described with reference to FIG. 20. Therefore, it is favorable that the on-chip capacitor CC is provided.

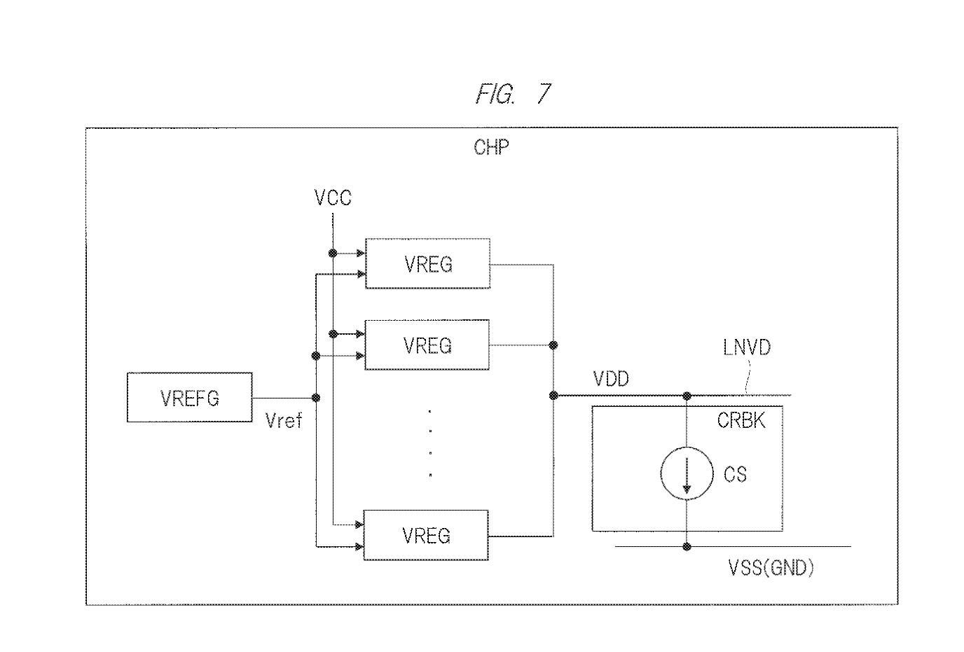

FIG. 7 is a circuit block diagram illustrating an example of an actual configuration of the peripheral circuits of the power-source voltage regulator circuit in the semiconductor device of FIG. 1. Actually, a plurality of power-source voltage regulator circuits VREG illustrated in FIG. 6 are appropriately disposed in a distributed manner in the semiconductor chip CHP as illustrated in FIG. 7. In other words, each of the plurality of VREGs receives the power source voltage VCC and the reference voltage Vref from one reference voltage generating circuit VREFG to generate the internal power source voltage VDD, and outputs the VDD to the common power-source voltage line LNVD. The number of VREGs is determined according to a current supply capability of each VREG and the current consumption of the core circuit block CRBK. Further, the plurality of VREGs, for example, may be appropriately disposed in a distributed manner along the outer peripheral portion of the CRBK in FIG. 1, or in some cases disposed in the CRBK.

<<Arrangement of on-Chip Capacitor>>

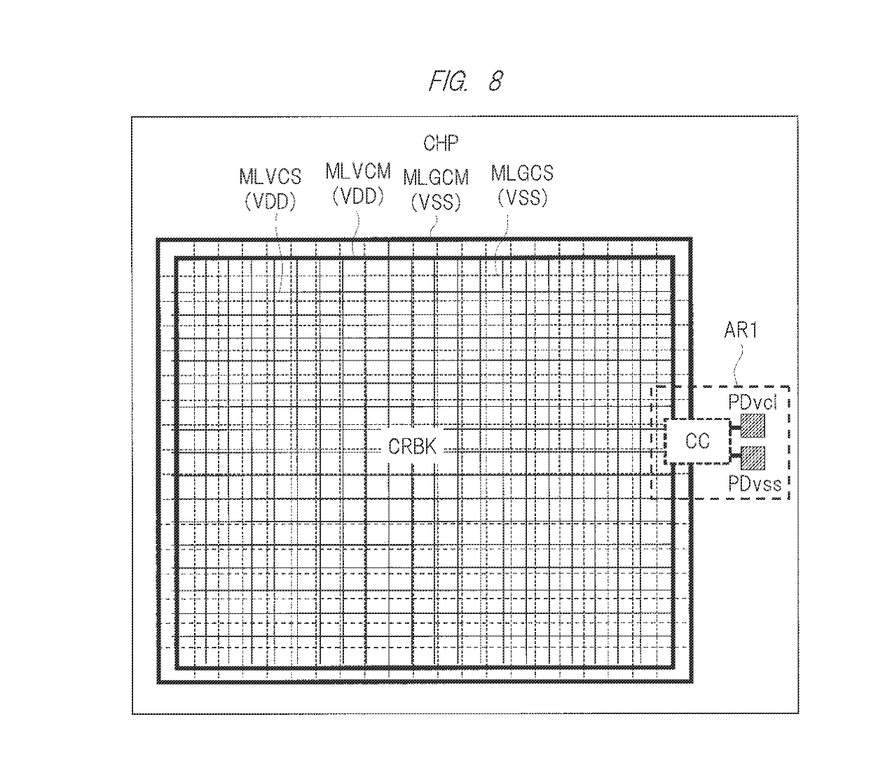

FIG. 8 is a plan view schematically illustrating an example of an arrangement of the on-chip capacitor in a semiconductor chip of the semiconductor device of FIG. 3. In FIG. 8, a forming region (a first region) of the core circuit block CRBK is disposed in the semiconductor chip CHP. Further, the main power-source voltage line MLVCM and the main reference power-source voltage line MLGCM are disposed along the outer peripheral portion of the first region (CRBK). The MLVCM and the MLGCM each have a ring shape herein, and are disposed to surround the CRBK. Inside the region surrounded by the MLVCM, the sub power-source voltage line MLVCS which is branched from the MLVCM and disposed in the mesh shape is disposed as described with reference to FIG. 1. Similarly, inside the region surrounded by the MLGCM, the sub reference power-source voltage line MLGCS which is branched from the MLGCM and disposed in the mesh shape is disposed. The MLVCM and the MLVCS correspond to the power-source voltage line (the first power-source voltage line) LNVD1 of FIG. 3.

In the region outside the forming region (the first region) of the core circuit block CRBK, the pad (the first power source pad) PDvcl for the internal power source voltage VDD and the pad PDvss for the reference power source voltage VSS are disposed. Herein, the on-chip capacitor CC is disposed in the forming region (the first region) of the CRBK and in the vicinity of the shortest route which connects the PDvcl and the PDvss. In other words, the forming region (the first region) of the CRBK is connected to the PDvcl and the PDvss, using lines as short as possible in actual layout, and is different from Patent Document 2 in which the lines are bypassed on purpose for the connection. With this configuration, as described with reference to FIG. 4, the impedance (R1) is easily designed to be lowered.

As can be seen from FIG. 3 and the like, in the on-chip capacitor CC, one end of the upper electrode (the first electrode) UPN is connected to the main power-source voltage line MLVCM, and the other end of the UPN is connected to the pad (the first power source pad) PDvcl. Further, one end of the lower electrode (the second electrode) LWN is connected to the main reference power-source voltage line MLGCM, and the other end of the LWN is connected to the pad PDvss. In such an exemplary arrangement, for example, the internal power source voltage VDD on the main power-source voltage line MLVCM and the sub power-source voltage line MLVCS also contains the power source noise generated in the core circuit block CRBK, and is applied to PDvcl certainly through the UPN. In other words, there is no power-source voltage route through which the power source noise generated in the CRBK is transferred to the PDvcl without passing the CC. Therefore, it is possible to reliably reduce the EMI noise (emission noise).

<<Types of on-Chip Capacitors>>

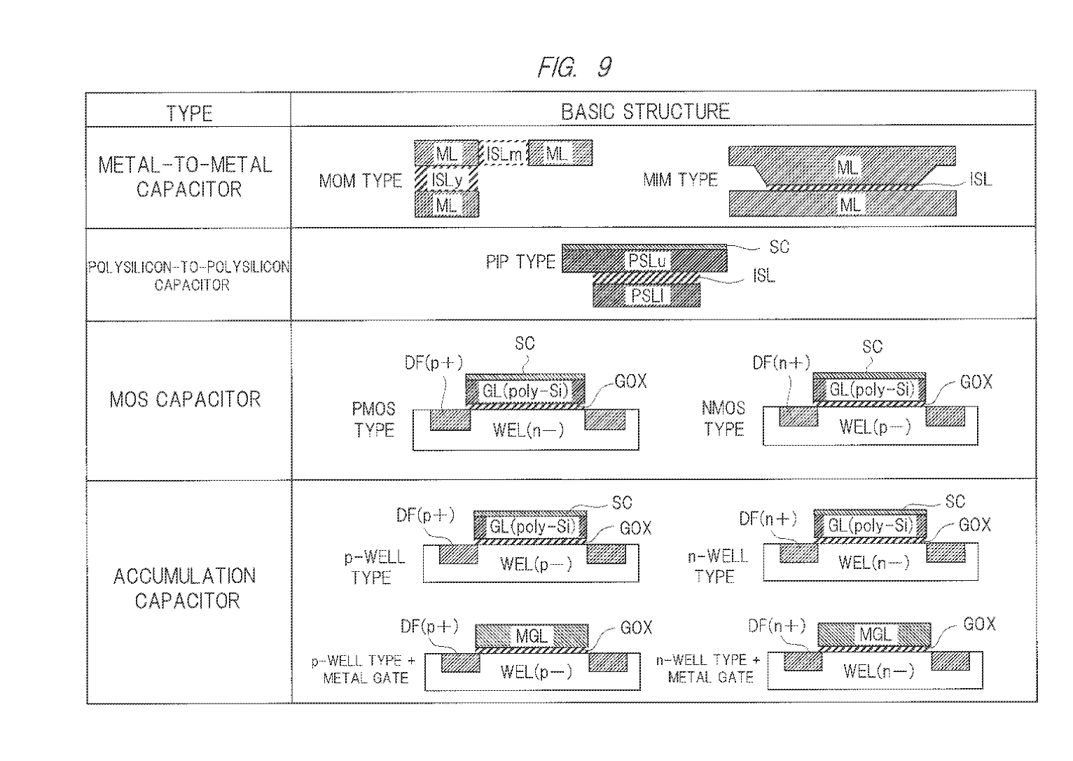

FIG. 9 is a diagram schematically illustrating various structures of the on-chip capacitor in the semiconductor device of FIG. 3. In FIG. 9, first, as an on-chip capacitor CC using capacitance between metal lines, a MOM type capacitor and a MIM type capacitor can be exemplified. The MOM type capacitor has a structure in which metal lines ML are closely disposed in the same metal line layer and a metal-to-metal insulating film ISLm therebetween is used as a capacitor, and the MLs are disposed in an overlapping manner in different metal line layers to use an interlayer insulating film ISLy therebetween as a capacitor. The MIM type capacitor has a structure in which the metal lines ML are overlapped with a thin insulating film ISL disposed therebetween.

In these configurations, the metal lines ML are used as electrodes, so that an equivalent series resistance (ESR) of the electrode becomes small and they efficiently operate as the bypass capacitor. The MIM type capacitor can be made to have a large capacitance value per unit region compared to the MOM type capacitor, but it is not achieved by a general CMOS process but a special process is needed. For this reason, the MOM type capacitor is more desirable than the MIM type capacitor in consideration of manufacturing cost. In a case where the MOM type capacitor is used, a distance between electrodes (the metal lines ML) is shortened as the semiconductor device is miniaturized. Therefore, it is possible to increase the capacitance value.

Next, as an on-chip capacitor CC using a capacitor between polysilicon layers, a PIP type capacitor can be exemplified. The PIP type capacitor has a structure in which the insulating film ISL is mounted on a polysilicon layer PSL1 of a lower layer and a polysilicon layer PSLu is mounted on an upper layer thereof. A silicide layer SC is formed on the PSLu. The PIP type capacitor has a complicated process structure and the polysilicon electrode (specifically, on a side near the lower layer) has a large equivalent series resistance. Therefore, the above-mentioned MOM type capacitor is desirable.

Subsequently, as an on-chip capacitor CC using a MOS capacitance, a PMOS type capacitor and a NMOS type capacitor can be exemplified. The PMOS type capacitor has a structure in which a p-type diffusion layer DF(p+) for the source and the drain is formed in an n-type well WEL(n−) and a gate line GL is mounted on the WEL(n−) via a gate insulating film GOX. The NMOS type capacitor has a structure in which an n-type diffusion layer DF(n+) for the source and the drain is formed in a p-type well WEL(p−) and the gate line GL is mounted on the WEL(p−) via the gate insulating film GOX. In addition, for example, the GL as well as the PMOS type capacitor and the NMOS type capacitor is formed of polysilicon, and the silicide layer SC is formed on the GL.

The PMOS type capacitor and the NMOS type capacitor can be made to have a large capacitance value per unit region, but has a demerit that the equivalent series resistance of the electrode is large. In other words, one electrode has a large equivalent series resistance due to the gate line GL (that is, polysilicon), but the equivalent series resistance can be lowered by the silicide layer SC to some degree. However, since the other electrode serves as a channel portion in the well WEL, the equivalent series resistance of the portion is easily lowered. Therefore, the above-mentioned MOM type capacitor is desirable.

Finally, as an on-chip capacitor CC using an accumulation capacitor, a p-well type capacitor, an n-well type capacitor, and capacitors in which the metal gate is combined with these capacitors can be exemplified. The p-well type capacitor has a structure in which a p-type diffusion layer DF(p+) having impurity concentration higher than that of the p-type well WEL(p−) is formed in the p-type well and the gate line GL is mounted on the WEL(p−) via the gate insulating film GOX. The n-well type capacitor has a structure in which an n-type diffusion layer DF(n+) having impurity concentration higher than that of the n-type well WEL(n−) is formed in the n-type well and the gate line GL is mounted on the WEL(n−) via the gate insulating film GOX. In addition, for example, the GL as well as the p-well type capacitor and the n-well type capacitor is formed of polysilicon, and the silicide layer SC is formed on the GL. The p-well type capacitor and the n-well type capacitor are structured to be changed in polarity of the diffusion layer in the above-mentioned NMOS type capacitor and PMOS type capacitor. Such a structure will be referred to as an accumulation capacitor in this specification.

Unlike the case of the PMOS type capacitor and the NMOS type capacitor, the accumulation capacitor has the other electrode (for example, the lower electrode LWN in FIG. 6) which is formed as a well WEL, so that the equivalent series resistance, for example, can be reduced by increasing the region of the WEL. Therefore, it is favorable that the accumulation capacitor be used as the on-chip capacitor CC besides the above-mentioned MOM type capacitor. However, similarly to the case of the above-mentioned PMOS type capacitor and NMOS type capacitor, there is a concern that the accumulation capacitor causes an equivalent series resistance to some degree in one electrode (for example, the upper electrode UPN in FIG. 6). Therefore, it is desirable to use a structure in which the gate line GL in the p-well type capacitor and the n-well type capacitor is replaced with a metal gate line MGL. The MGL, for example, is formed using a metal material such as titanium (Ti).

As described above, it is desirable to use the MOM-type metal-to-metal capacitor or the accumulation capacitor as the on-chip capacitor CC. Therefore, it is possible to make the CC efficiently operate as the bypass capacitor. In addition, regardless of which capacitor is used, the partial section of the power-source voltage line (the second power-source voltage line) LNVD2 is configured to serve as the upper electrode (the first electrode) UPN of the CC as described with reference to FIG. 3. For example, in a case where the MOM type capacitor is used, the metal line ML may be just used as a part of the LNVD2, and in a case where the accumulation capacitor is used, the gate line GL (or the metal gate line MGL) may be just used as a part of the LNVD2.

Hitherto, the reduction of the EMI noise (emission noise) can be representatively achieved by using the semiconductor device of the first embodiment.

### Second Embodiment

In the second embodiment, a case where the MOM-type metal-to-metal capacitor is used as the on-chip capacitor CC described in the first embodiment will be given as an example, and the details thereof will be described.

<<Details of Peripheral Circuits of on-Chip Capacitor [1]>>

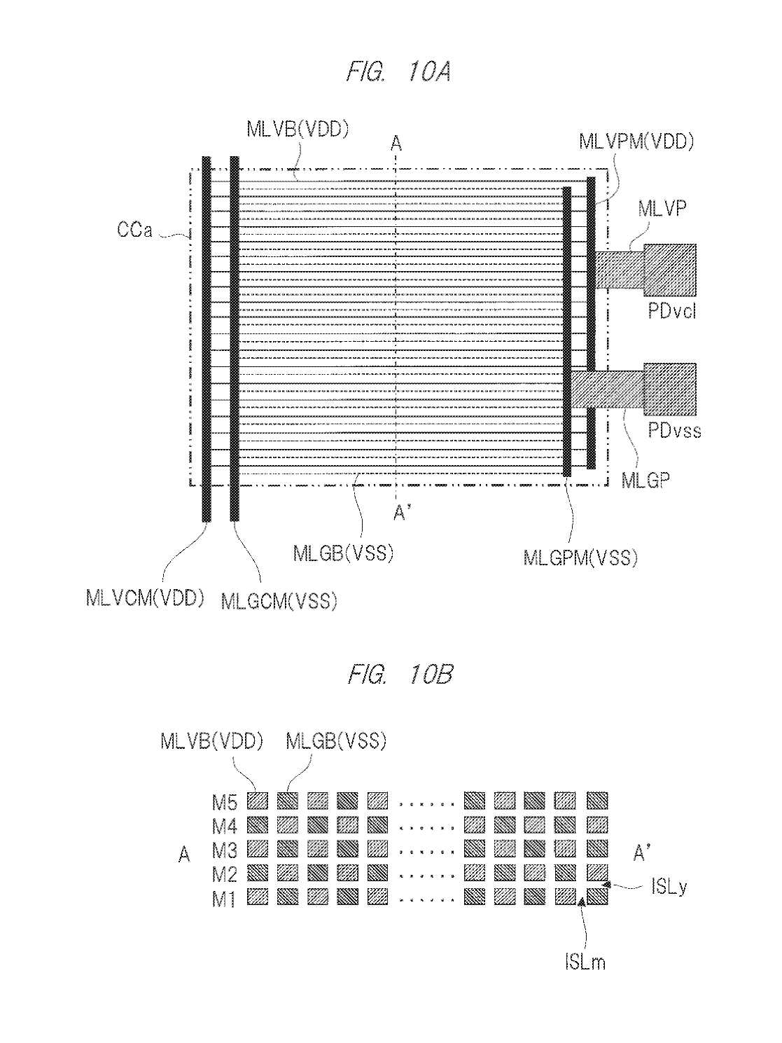

FIG. 10A is a plan view schematically illustrating an example of a layout configuration of an on-chip capacitor of a semiconductor device according to a second embodiment of the invention, and FIG. 10B is a cross-sectional view illustrating an exemplary structure taken along the line A-A′ of FIG. 10A. The on-chip capacitor CCa illustrated in FIG. 10A is disposed as the on-chip capacitor CC which is above mentioned in FIG. 8. In addition to the main power-source voltage line MLVCM and the main reference power-source voltage line MLGCM illustrated in FIG. 8, the CCa includes a pad side power-source voltage line MLVPM, a pad side reference power-source voltage line MLGPM, a plurality of branch power-source voltage lines MLVB, and a plurality of branch reference power-source voltage lines MLGB. The MLVCM, the MLGCM, the MLVPM, and the MLGPM are paralleled to each other and stretch in the same direction. The plurality of MLVBs and MLGBs are paralleled to each other and stretch in a direction (a first direction) intersecting with the stretching direction of the MLVCM, the MLGCM, the MLVPM, and the MLGPM.

The plurality of branch power-source voltage lines (first metal lines) MLVB is configured such that one ends are commonly connected to the main power-source voltage line (a first node) MLVCM and the other ends are commonly connected to the pad side power-source voltage line (a second node) MLVPM. The plurality of branch reference power-source voltage lines (second metal lines) MLGB is configured such that one ends are commonly connected to the main reference power-source voltage line MLGCM and the other ends are commonly connected to the pad side reference power-source voltage line MLGPM. The plurality of MLGBs and the plurality of MLVBs are alternately disposed at a predetermined interval with insulating films (not illustrated) interposed therebetween. Each of the plurality of MLVBs and MLGBs, for example, is formed of a line thinner than the MLVCM, the MLGCM, the MLVPM, and the MLGPM. The MLVPM is connected to the pad PDvcl through a power-source voltage line MLVP, and the MLGPM is connected to the pad PDvss through a reference power-source voltage line MLGP.

As illustrated in FIG. 10B, the on-chip capacitor CCa of FIG. 10A is formed using a plurality of metal line layers on the semiconductor substrate (not illustrated), metal-to-metal insulating films which separate the respective metal lines in the same metal line layer, and interlayer insulating films which separate the different metal line layers. In the example, it is assumed that a first metal line layer M1 to a fifth metal line layer M5 are sequentially disposed in an upward direction and the same layout rule (that is, the same minimum line width and the same minimum interline pitch) is applied. The CCa is formed using the M1 to the M5, the metal-to-metal insulating film ISLm, and the interlayer insulating film ISLy.

In FIG. 10B, the respective branch power-source voltage lines (the first metal lines) MLVB and the respective branch reference power-source voltage lines (the second metal lines) MLGB are alternately disposed with the metal-to-metal insulating film ISLm interposed therebetween in the same layer of the plurality of metal line layers (M1 to M5). Further, the respective MLVBs and the respective MLGBs are alternately disposed with the interlayer insulating film ISLy interposed therebetween even in the layer direction the plurality of metal line layers (M1 to M5). With reference to FIG. 3 above, the plurality of MLVBs form the upper electrodes (the first electrodes) UPN, and the plurality of MLGBs forms the lower electrodes (the second electrodes) LWN. Specifically, the MLVB and the MLGB are formed in the same metal line layer at the minimum interline pitch of the layout rule, but not limited thereto.

Further, in FIG. 10A, the power-source voltage line MLVP, for example, is formed by a seventh metal line layer (M7) and connected to the pad PDvcl which is formed in the uppermost layer. The reference power-source voltage line MLGP, for example, is formed by a sixth metal line layer (M6) and connected to the pad PDvss which is formed in the uppermost layer via the M7. For example, as illustrated in FIG. 10B, the respective branch power-source voltage lines (the first metal lines) MLVB and the pad side power-source voltage line (the second node) MLVPM, and the respective branch reference power-source voltage lines (the second metal lines) MLGB and the pad side reference power-source voltage line MLGPM are appropriately formed using the first metal line layer M1 to the fifth metal line layer M5. In this case, the MLVPM and the MLVP, and the MLGPM and the MLGP each are appropriately connected through the contact layer.

As described above, the on-chip capacitor CCa of FIG. 10A is configured to connect the pads PDvcl and PDvss and the main power-source voltage line MLVCM and the main reference power-source voltage line MLGCM on a side near the core circuit block using substantially the shortest lines. Further, partial sections of the lines (that is, the respective branch power-source voltage line MLVB and the respective branch reference power-source voltage line MLGB) are also used as the electrodes of the CCa. Therefore, a state of the low impedance (R1) described above with reference to FIG. 4 can be achieved, and the CCa can be efficiently operated as the bypass capacitor. Further, when the power source noise generated between the MLVCM and the MLGCM is transferred to the PDvcl and the PDvss, the power source noise certainly passes through the CCa, so that EMI (emission noise) in the PDvcl and the PDvss can be sufficiently reduced.

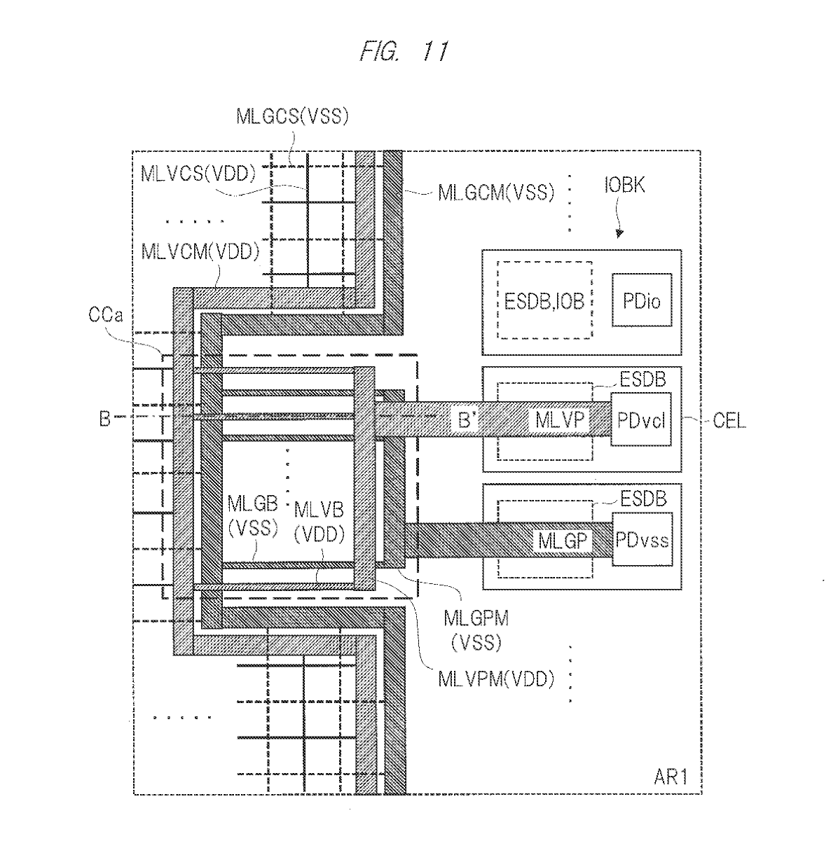

FIG. 11 is a plan view illustrating an exemplary configuration of a detailed layout of the peripheral circuits of the on-chip capacitor of FIG. 8, in which the on-chip capacitor of FIGS. 10A and 10B including the peripheral circuits are illustrated in more detail. FIG. 11 illustrates the above-mentioned region AR1 in FIG. 8 in detail. In the example of FIG. 11, a part of the forming region (the first region) of the core circuit block CRBK of FIG. 8 is cut in a concave shape from the outer peripheral side toward the inner side, and the on-chip capacitor CCa as illustrated in FIG. 10A is disposed in the concave region. With this configuration, it is possible to prevent an increase in size of the semiconductor chip CHP, and form the CCa having a sufficient capacitance value.

Further, the pads PDvcl and PDvss each are formed in each cell CEL in the external input/output block (IO block) IOBK as illustrated in FIG. 11. Each CEL includes a protection circuit ESDB for preventing electrostatic discharge damage in addition to the pad. For example, the ESDB in the CEL which includes the pad (the first power source pad) PDvcl is connected to a node of the power-source voltage line MLVP which is positioned between the upper electrode (the first electrode) (herein, the branch power-source voltage line MLVB) of the on-chip capacitor CCa and the pad (the first power source pad) PDvcl. In addition, for example, the CEL which includes a pad PDio used for an external input/output data signal further includes an input/output buffer circuit IOB in addition to the ESDB.

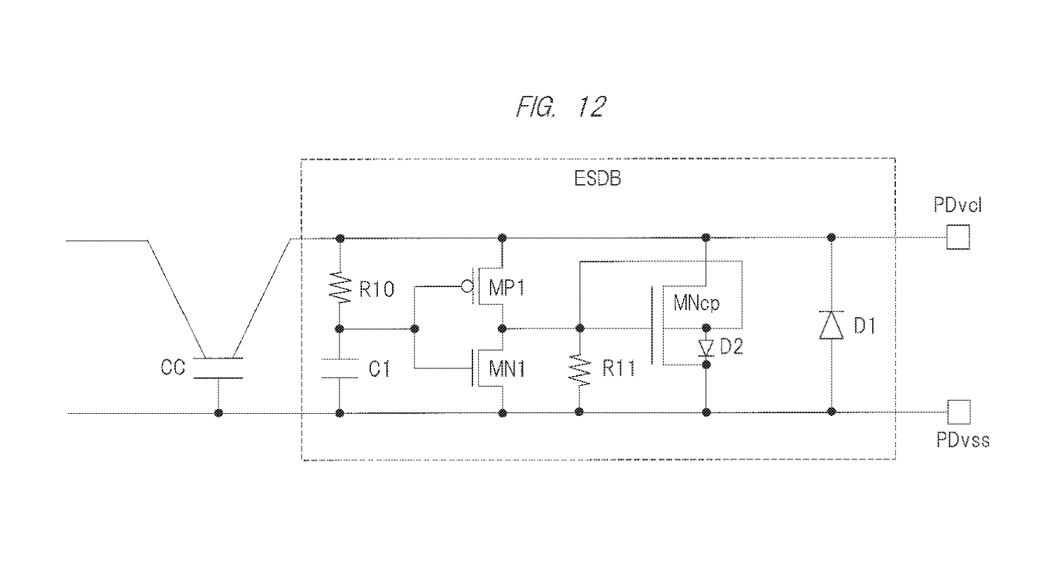

FIG. 12 is a circuit diagram illustrating an example of a detailed configuration of a protection circuit for preventing electrostatic discharge damage of FIG. 11. The protection circuit ESDB illustrated in FIG. 12 includes a PMOS transistor MP1, an NMOS transistor MN1, resistors R10 and R11, a capacitor C1, a clamping NMOS transistor MNcp, and parasitic diodes D1 and D2. For example, in a case where a surge voltage is applied to the pad PDvss, the pads PDvcl and PDvss are clamped through the D1. Further, for example, in a case where a surge voltage is applied to the PDvcl, while the power source voltage of the MP1 is steeply increased, the gate voltage of the MP1 is gradually increased according to a time constant of the C1 and the R10. During a period of the gradual increase, the MP1 is turned on, and the MNcp is also turned on to clamp the PDvcl and the PDvss.

As described above, in the protection circuit ESDB, the capacitor C1 as illustrated in FIG. 12 may be provided or a capacitor may be further provided between the line from the pad PDvcl and the line from the pad PDvss. However, these capacitors, for example, are achieved by general MOS transistor capacitors, and different from the on-chip capacitor CC according to the embodiment. In other words, as already described with reference to FIG. 5, the general MOS transistor capacitor or the like, for example, has a structure in which a partial section of the line from the PDvcl does not serve as the electrode of the capacitor but the electrode of the capacitor is connected to a destination branched from the node on the line.

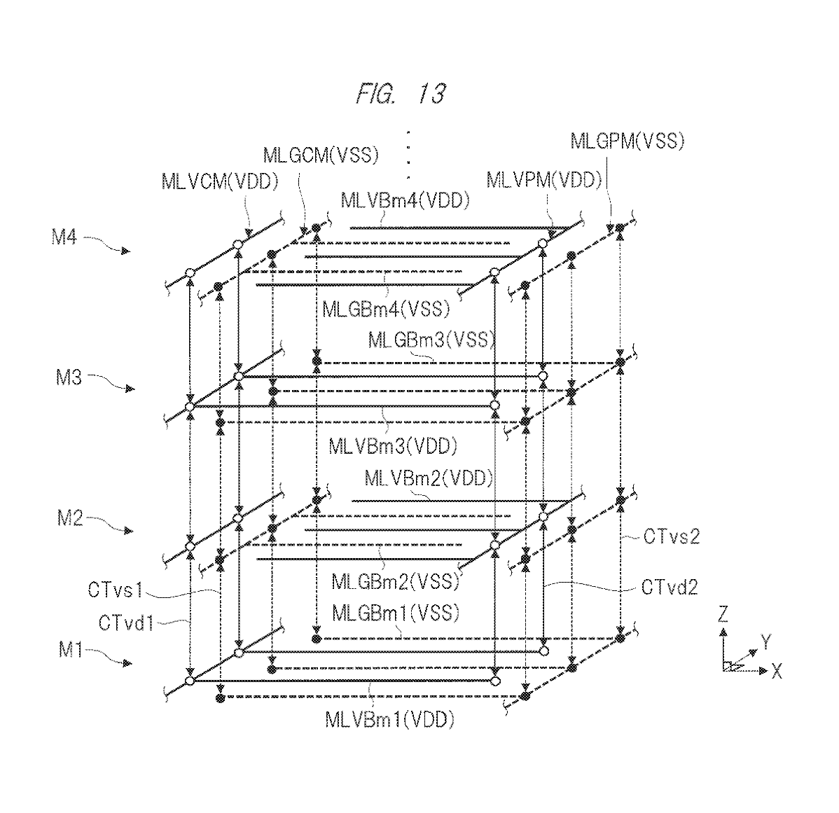

FIG. 13 is a three-dimensional view schematically illustrating an exemplary configuration of part of the on-chip capacitor of FIGS. 10A and 10B. In the example of FIG. 13, first, the power-source voltage line is disposed in a comb shape; that is, in the first metal line layer M1, the main power-source voltage line MLVCM on a side near the core circuit block is formed as a comb shaft, a plurality of branch power-source voltage lines MLVBm1 are formed as teeth, and the plurality of teeth is branched from the comb shaft. On the other hand, in a second metal line layer M2, the power-source voltage line is disposed in a comb shape in which the pad side power-source voltage line MLVPM is formed as a comb shaft and a plurality of branch power-source voltage lines MLVBm2 are formed as teeth. Further, an interlayer connecting power-source voltage line is disposed in the M2 at the same XY coordinates as the MLVCM in the M1.

The comb teeth-shaped power-source voltage line in the second metal line layer M2 is formed such that the comb teeth-shaped power-source voltage line in the first metal line layer M1 is disposed to be symmetrical about the Y axis, the XY coordinates of the teeth are set to be shifted by one pitch in the Y axial direction, and lengths of the teeth in the X axial direction are shorter than those of the teeth in the M1. Herein, the one pitch is referred to as an interval between the branch power-source voltage line MLVB and the branch reference power-source voltage line MLGB which are adjacent to each other in the same metal line layer.

In the comb teeth-shaped power-source voltage line in the first metal line layer M1, one ends of contact layers CTvd2 are connected to the tip ends of the plurality of teeth branched from the comb shaft. Further, in the comb teeth-shaped power-source voltage line in the second metal line layer M2, the other ends of the contact layers CTvd2 are connected to the center positions, each of which is positioned between a branch point of a tooth from the comb shaft and a branch point of the adjacent tooth from the comb shaft. Furthermore, in the comb teeth-shaped power-source voltage line in the M1, one ends of contact layers CTvd1 are connected to predetermined positions (herein, the branch points of the plurality of teeth) on the comb shaft, and in the M2, the other ends of the contact layers CTvd1 are connected to the interlayer connecting power-source voltage line.

Similarly, in an odd-numbered metal line layer, the comb teeth-shaped power-source voltage line having the same XY coordinates as the comb teeth-shaped power-source voltage line in the first metal line layer M1 is disposed. In the even-numbered metal line layer, the comb teeth-shaped power-source voltage line and the interlayer connecting power-source voltage line having the same XY coordinates as the comb teeth-shaped power-source voltage line and the interlayer connecting power-source voltage line in the second metal line layer M2 are disposed. Then, these power-source voltage lines are appropriately connected to the CTvd1 and the CTvd2 having the same XY coordinates as the above-mentioned contact layers CTvd1 and CTvd2.

Next, the reference power-source voltage line is disposed in a comb shape; that is, in the odd-numbered metal line layer, the comb teeth-shaped power-source voltage line in the odd-numbered metal line layer described above is disposed to be symmetrical about the Y axis, and the XY coordinates of the teeth are set to be shifted by one pitch in the Y axial direction. Similarly, also in the even-numbered metal line layer, the comb teeth-shaped power-source voltage line and the interlayer connecting power-source voltage line in the even-numbered metal line layer described above are disposed to be symmetrical about the Y axis, and an comb teeth-shaped reference power-source voltage line and an interlayer connecting reference power-source voltage line are disposed at the XY coordinates shifted by one pitch in the Y axial direction. Then, as is the case with the above-mentioned contact layers CTvd1 and CTvd2, these respective reference power-source voltage lines are appropriately connected through the contact layers CTvs1 and CTvs2 by making the connection points different in the odd-numbered and even-numbered metal line layers. As such an example, the on-chip capacitor CCa as illustrated in FIGS. 10A and 10B can be achieved by appropriately changing the contact layers (or vias).

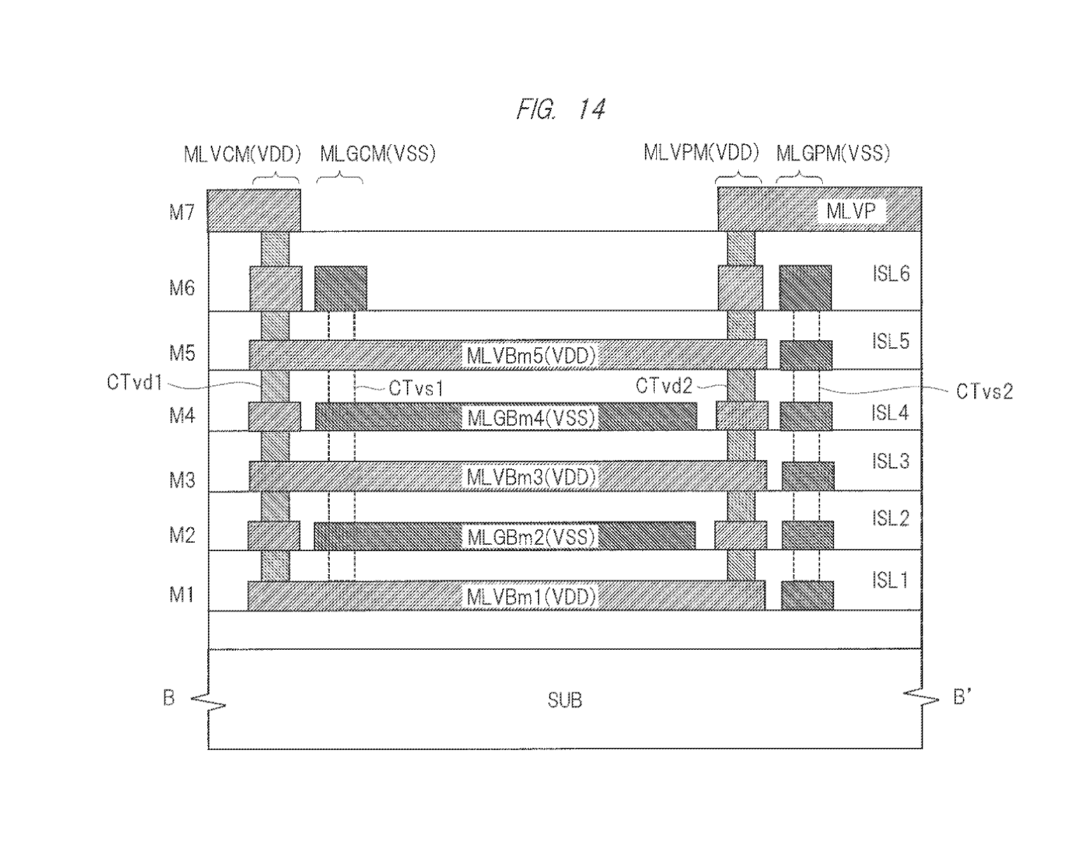

FIG. 14 is a cross-sectional view illustrating an exemplary structure of the on-chip capacitor taken along the line B-B′ of FIG. 11. Herein, the case of the on-chip capacitor having the three-dimensional structure as illustrated in FIG. 13 will be given as an example. In FIG. 14, the first metal line layer M1, the second metal line layer M2, . . . , and the seventh metal line layer M7 are sequentially provided in the upward direction of a semiconductor substrate SUB. In the M1 to the M7, metal lines made of cupper (Cu) or the like are appropriately formed for example. The metal lines in the M1 to the M7 are insulated by interlayer insulating films ISL1 to ISL6, respectively. In the M1, the M3, and the M5, branch power-source voltage lines MLVBm1, MLVBm3, and MLVBm5 stretching in the first direction are formed as described with reference to FIG. 10. Further, in the M2 and the M4 interposed by the M1, the M3, and the M5, branch reference power-source voltage lines MLGBm2 and MLGBm4 stretching in the first direction are formed.

One ends of the branch power-source voltage lines MLVBm1, MLVBm3, and MLVBm5 are commonly connected through a common connecting portion corresponding to the main power-source voltage line MLVCM on a side near the core circuit block. In addition to the one ends of the MLVBm1, the MLVBm3, and the MLVBm5, the common connecting portion includes the respective metal lines formed in the second metal line layer M2, the fourth metal line layer M4, the sixth metal line layer M6, and the seventh metal line layer M7, and the contact layers CTvd1 which connect the respective metal lines. Similarly, the other ends of the MLVBm1, the MLVBm3, and the MLVBm5 are commonly connected through a common connecting portion corresponding to the pad side power-source voltage line MLVPM. In addition to the one ends of the MLVBm1, the MLVBm3, and the MLVBm5, the common connecting portion includes the respective metal lines formed in the M2, the M4, the M6, and the M7, and the contact layers CTvd2 which connect the respective metal lines.

On the other hand, one ends of the branch reference power-source voltage lines MLGBm2 and MLGBm4 are commonly connected through a common connecting portion corresponding to the main reference power-source voltage line MLGCM on a side near the core circuit block. In addition to the one ends of the MLGBm2 and the MLGBm4, the common connecting portion includes the respective metal lines formed in the first metal line layer M1, the third metal line M3, the fifth metal line layer M5, and the sixth metal line layer M6, and the contact layers CTvs1 which connect the metal lines. In addition, as can be seen from FIG. 13, the respective metal lines of the M1, the M3, and the M5 and the CTvs1 are actually disposed from the front side to the inner side with respect to the sheet of FIG. 14.

Further, the pad side reference power-source voltage line MLGPM is disposed adjacent to the pad side power-source voltage line MLVPM. The MLGPM includes the respective metal lines formed in the first metal line layer M1 to the sixth metal line layer M6, and the contact layers CTvs2 which connect the respective metal lines. In addition, as can be seen from FIG. 13, the contact layers CTvs2 are actually disposed from the front side to the inner side with respect to the sheet of FIG. 14. As can be seen from FIG. 13, the main reference power source voltage line MLGCM is connected to the MLGPM through metal lines (not illustrated) which are formed in the first metal line layer M1, the third metal line layer M3, and the fifth metal line layer M5.

The metal line serving as a part of the pad side power-source voltage line MLVPM on the seventh metal line layer M7 is connected to the power-source voltage line MLVP illustrated in FIG. 11. The metal line serving as a part of the pad side reference power-source voltage line MLGPM on the sixth metal line layer M6 is connected to the reference power-source voltage line MLGP illustrated in FIG. 11 at a place (not illustrated). In addition, the on-chip capacitor CCa as illustrated in FIGS. 10A and 10B can be achieved by various structures other than the structure of FIG. 13, and accordingly the cross-sectional structure of FIG. 14 can also be appropriately changed. However, there is no change in that the respective branch power-source voltage lines (herein, the MLVBm1, the MLVBm3, and the MLVBm5) and the respective branch reference power-source voltage lines (herein, the MLGBm2 and the MLGBm4) are alternately disposed in the layer direction.

Hitherto, in addition to the various effects as described in the first embodiment, it is possible to achieve the on-chip capacitor which efficiently operates as the bypass capacitor by using the semiconductor device of the second embodiment. Further, the reduction of the EMI noise (emission noise) or the like can be representatively achieved.

### Third Embodiment

In the third embodiment, a case where the accumulation capacitor is used as the on-chip capacitor CC described in the first embodiment will be given as an example, and the details thereof will be described.

<<Details of Peripheral Circuits of on-Chip Capacitor [2]>>

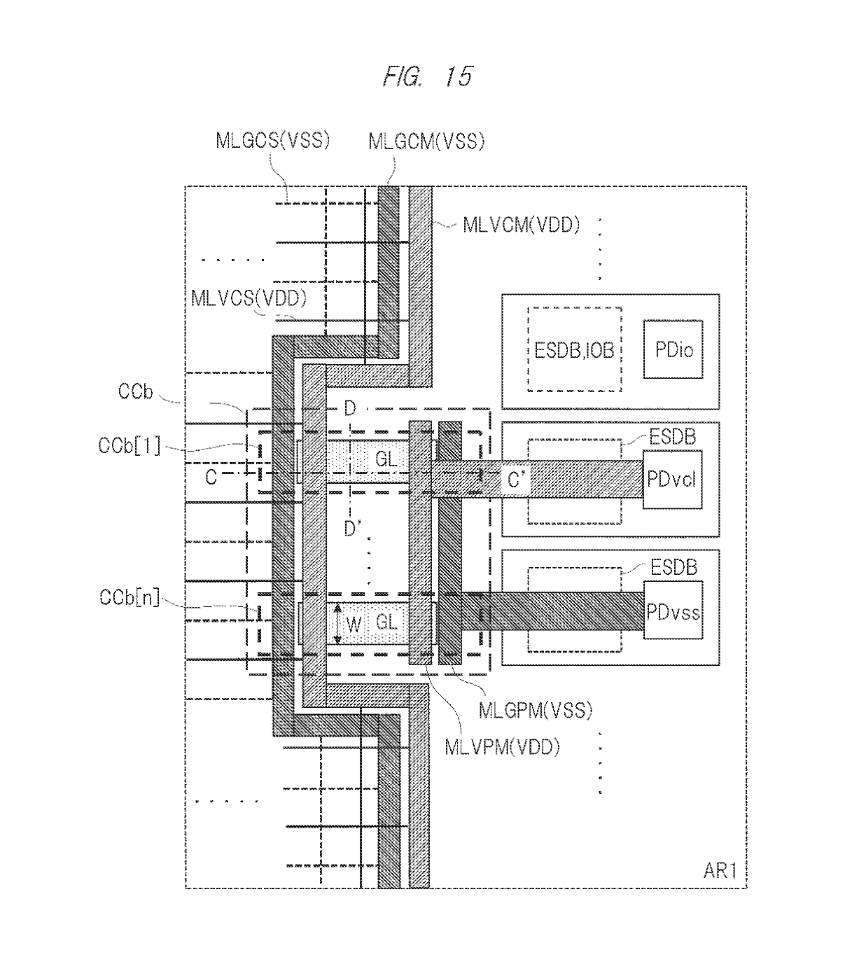

FIG. 15 is a plan view illustrating an exemplary configuration of a detailed layout of the peripheral circuits of the on-chip capacitor of FIG. 8 in a semiconductor device according to a third embodiment of the invention. FIG. 15 illustrates the above-mentioned region AR1 in FIG. 8 in detail. In the exemplary layout configuration of FIG. 15, as is the case with FIG. 11, a part of the forming region (the first region) of the core circuit block CRBK of FIG. 8 is cut in a concave shape from the outer peripheral side toward the inner side, and the on-chip capacitor CCa is disposed in the concave region. However, unlike the CCa of FIG. 11, the CCb includes the accumulation capacitor, and a plurality of unit on-chip capacitors CCb[1] to CCb[n].

Each of the unit on-chip capacitors CCb[1] to CCb[n] includes the gate line GL. While being described in detail below, the respective GLs are power-source voltage lines which are connected in parallel between the main power-source voltage line MLVCM and the pad side power-source voltage line MLVPM, and also serve as the upper electrodes of the on-chip capacitors CCb. In addition, the reason why the CCb is divided into the CCb[1] to the CCb[n] is that the layout of the GL is restricted. However, in a case where the gate width (W) is sufficient for forming a wide GL, there is no need to divide the capacitor.

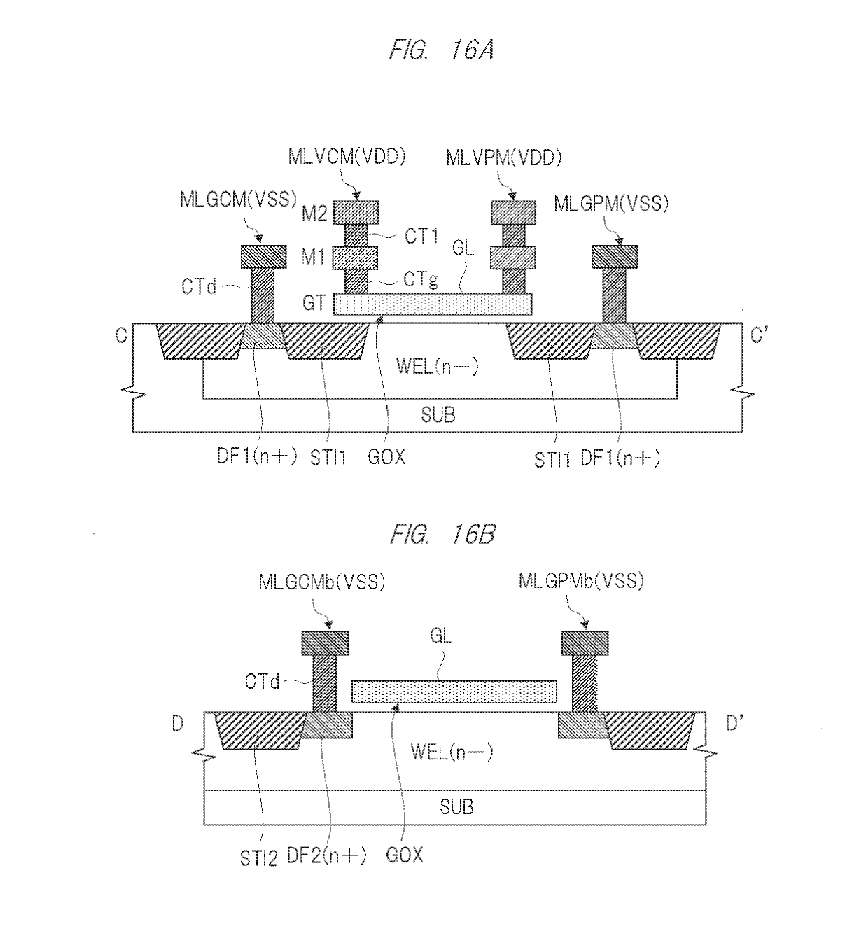

Further, herein, when compared with FIG. 11, a positional relation between the main power-source voltage line MLVCM and the main reference power-source voltage line MLGCM is exchanged for convenience's sake. This is because there is a need to match the structure with the following structure of FIG. 16A. However, for example, the lines are once extracted out of the MLVCM and the MLGCM toward the pads (PDvcl and the like) just as the positional relation of FIG. 11, and the positional relation at the lead-out places can be easily exchanged, so that a difference from the above-mentioned positional relation is not essential. Since the other configurations are equal to those of FIG. 11, the descriptions thereof will not be repeated.

FIG. 16A is a cross-sectional view illustrating an exemplary structure of a unit on-chip capacitor taken along the line C-C′ of FIG. 15, and FIG. 16B is a cross-sectional view illustrating an exemplary structure of the unit on-chip capacitor taken along the line D-D′ of FIG. 15. In FIG. 16A, the n-type well WEL(n−) is formed in the semiconductor substrate SUB. In the WEL(n−), two n-type diffusion layers DF1(n+) having the impurity concentration higher than that of the WEL(n−) are formed. In a region interposed by the two n-type diffusion layers DF1(n+), two element-separation insulating films STI1 are disposed adjacent to each of the two n-type diffusion layers DF1(n+).

The gate line GL is formed via the gate insulating film GOX over the region interposed by two element-separation insulating films STI1 in the well WEL(n−). The GL is positioned in a gate layer GT, and is formed in a laminated structure of the polysilicon layer and the silicide layer for example. The GOX, for example, is formed of silicon dioxide (SiO₂) or the like. The silicide layer, for example, is formed of tungsten (W), molybdenum (Mo), titanium (Ti) or the like.

Both ends of the gate line GL each are connected to two metal lines in the first metal line layer M1 through the contact layers CTg, and the two metal lines each are connected to two metal lines in the second metal line layer M2 through the contact layers CT1. One of the two metal lines in the M2 serves as a part of the main power-source voltage line MLVCM, and the other one serves as a part of the pad side power-source voltage line MLVPM. Further, the two diffusion layers DF1(n+) each is connected to two metal lines in the M1 through the contact layers CTd. One of the two metal lines in the M1 serves as a part of the main reference power-source voltage line MLGCM, and the other one serves as a part of the pad side reference power-source voltage line MLGPM. In addition, the metal line is formed of cupper (Cu) or the like for example.

In FIG. 16B, the n-type well WEL(n−) is formed in the semiconductor substrate SUB. Two n-type diffusion layers DF2(n+) having impurity concentration higher than that of the WEL(n−) are formed in the WEL(n−). Further, in the WEL(n−), two element-separation insulating films STI2 are disposed adjacent to each of the two n-type diffusion layers DF2(n+) so as to interpose the two n-type diffusion layers DF2(n+). The gate line GL is formed via the gate insulating film GOX over the region interposed by the two n-type diffusion layers DF2 (n+) in the WEL(n−). The two n-type diffusion layers DF2(n+) each are connected to two metal lines in the M1 through the contact layers CTd. While not particularly limited, one of two metal lines in the M1 is a main reference power-source voltage line MLGCMb (not illustrated in FIG. 15) which is extracted out of the main reference power-source voltage line MLGCM, and the other one is a pad side reference power-source voltage line MLGPMb (not illustrated in FIG. 15) which is extracted out of the pad side reference power-source voltage line MLGPM.

<<Equivalent Circuit of Accumulation Capacitor>>

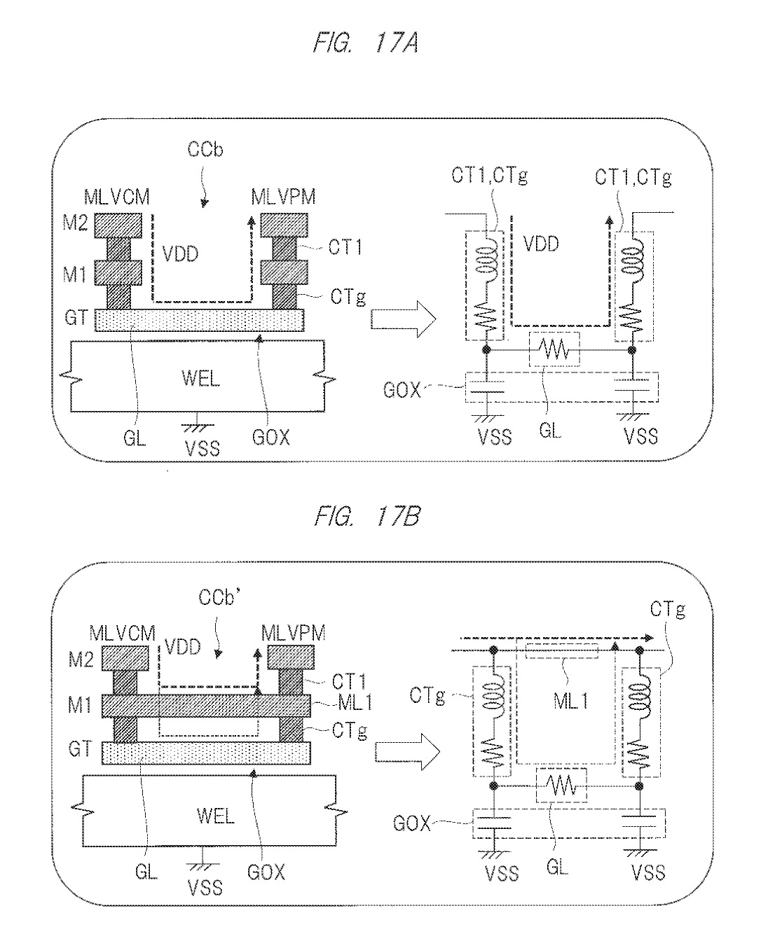

FIG. 17A is a diagram illustrating an example of the simplified cross-sectional structure of FIG. 16A and the equivalent circuit thereof, and FIG. 17B is a diagram illustrating an example of a cross-sectional structure as a comparative example of FIG. 17A and the equivalent circuit thereof. As illustrated in FIGS. 16A and 16B, the reference power source voltage VSS (the ground power source voltage GND) is supplied to the well WEL(n−) through the reference power-source voltage line and the diffusion layers DF1(n+) and DF2(n+). Then, in the on-chip capacitor CCb of FIG. 17A, the well WEL is connected to the VSS. For example, with reference to FIG. 3, the WEL in FIG. 17A serves as the lower electrode (the second electrode) LWN of the CCb, and the gate line GL in FIG. 17A serves as the upper electrode (the first electrode) UPN of the CCb.

As illustrated in FIG. 17A, the internal power source voltage VDD containing the power source noise applied from the main power-source voltage line MLVCM reaches one end of the gate line GL through the contact layers CT1 and CTg, and after passing through the GL, reaches the pad side power-source voltage line MLVPM from the other end of the GL through the CTg and the CT1. In this case, having an equivalent series resistance component and a parasitic inductance component to some degree, the CTg and the CT1 are expressed as a series circuit of an inductor and a resistor in the equivalent circuit. Further, the GL has an equivalent series resistance component to some degree, and thus expressed as a resistor in the equivalent circuit. However, even though such parasitic components are present, there is only the GL in the supply path of the VDD, so that the VDD certainly passes through the GL serving as the upper electrode of the on-chip capacitor CCb. Therefore, the CCb efficiently operates as the bypass capacitor.

On the other hand, the on-chip capacitor CCb′ of FIG. 17B according to the comparative example includes a structure in which two metal lines in the first metal line layer M1 in FIG. 17A are commonly connected through a metal line ML1 in the M1. Such a structure corresponds to the circuit symbol as illustrated in FIG. 5B. In this case, much of the internal power source voltage VDD containing the power source noise applied from the main power-source voltage line MLVCM reaches the pad side power-source voltage line MLVPM in the path through the ML1. Therefore, the CCb′ acts a weak operation as the bypass capacitor compared to the CCb.

<<Structure of Metal Gate>>

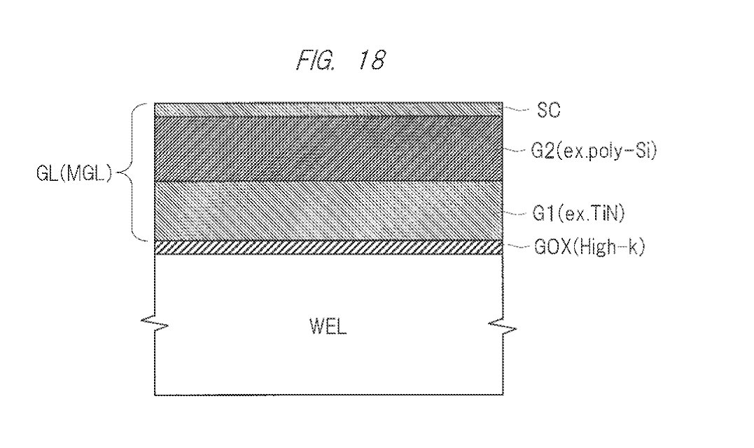

FIG. 18 is a cross-sectional view illustrating an exemplary structure of a metal gate which is used as a gate line of the on-chip capacitor of FIGS. 16A and 16B. The gate line GL serves as the power-source voltage line of the internal power source voltage VDD and also as the electrode of the capacitor. Therefore, as already described with reference to FIG. 4 of the first embodiment, it is desirable that the equivalent series resistance be lowered in order to further increase the effect of the bypass capacitor. Then, the gate line GL, for example, is desirably formed in the metal gate structure as illustrated in FIG. 18 rather than the laminating structure of the polysilicon layer and the silicide layer.

The gate line GL (the metal gate line MGL) illustrated in FIG. 18 has a structure in which three layers (G1, G2, and SC) are sequentially laminated from a side near the gate insulating film GOX. For example, the layer G1 is formed of titanium nitride (TiN), the layer G2 is formed of polysilicon, and the silicide layer SC is formed using nickel platinum. In addition, the SC may be formed using any one of nickel (Ni), titanium (Ti), cobalt (Co), platinum (Pt). Further, the GOX is formed of a high dielectric constant gate insulating film (so-called High-k). Specifically, hafnium oxide (HfO₂) having lanthanum oxide (La₂O₃) introduced therein, hafnium silicate oxide, hafnium silicate oxynitride, and the like can be exemplified.

In addition, as the process is miniaturized and the operating speed is increased, the respective transistors in the core circuit block CRBK tend to be manufactured using such a metal gate. Further, when the process is miniaturized and the operating speed is increased, the influence of noises (the power source noise and the EMI noise) tends to be remarkably exhibited. Therefore, it is desirable to employ the metal gate for both the respective transistors in the CRBK and the on-chip capacitor CCa. In this case, when the metal gate is formed in the respective transistors in the CRBK, the metal gate is also formed in the CCa in the same process, so that manufacturing cost or the like can be saved.

Hitherto, in addition to the various effects as described in the first embodiment, it is possible to achieve the on-chip capacitor which efficiently operates as the bypass capacitor by using the semiconductor device of the third embodiment. The reduction of the EMI noise (emission noise) or the like can be representatively achieved. In particular, in a case where the metal gate is used in order to increase the capacitance value of the insulting film as well as decrease the equivalent series resistance value of the electrode, the on-chip capacitor can efficiently operate as the bypass capacitor.

In addition, the n-type well is used as a well in the examples of FIG. 16A and FIG. 16B, but the p-type well can also be used in some cases. In other words, it is also possible to employ the structure of the p-well type capacitor illustrated in FIG. 9. However, since the n-type well has an equivalent series resistance smaller than that of the p-type well, the n-type well is desirably used from the viewpoint of making a low resistive electrode. Further, from the viewpoint of making a low resistive electrode, for example, it is favorable that a region of the well positioned in the region of the on-chip capacitor CCb is increased as large as possible as illustrated in FIG. 15.

In the foregoing, the invention made by the inventor of the present invention has been concretely described based on the embodiments. However, it is needless to say that the present invention is not limited to the foregoing embodiments and various modifications and alterations can be made within the scope of the present invention. For example, the embodiments described above have been described in detail for facilitating understanding of the invention and thus they are not necessarily limited to those having all of the components described above. In addition, apart of a configuration of one embodiment can be replaced with another configuration of another embodiment and also another configuration of another embodiment can be added to one configuration of one embodiment. Moreover, as to a part of a configuration of each of the embodiments, another configuration can be added to it, eliminated from it, or replaced with it.

For example, herein, an example of the microcomputer has been described as the semiconductor device, but the invention is not limited to the microcomputer of course. The invention can also be applied to various semiconductor products required for noise countermeasures.

### EXPLANATION OF REFERENCE NUMERALS

AMP Amplifier circuit
ANGBK Analog circuit block
AR Region
BD Wiring board
BGR Bandgap reference circuit
BW Bonding wire
C Capacitor
CC, CC′ On-chip capacitor
CE External capacitor
CEL Cell
CHP Semiconductor chip
CKBK Clock generating circuit block
CP Capacity
CPU Processor circuit
CRBK Core circuit block
CS Current source
CT Contact layer
D Parasitic diode
DF Diffusion layer
ESDB Protection circuit
G Layer
GL Gate line
GOX Gate insulating film
GT Gate layer
ICP IC package
IOB Input/output buffer circuit
IOBK External input/output block
IS, ISL Insulating film
LNVD Power-source voltage line
LNVS Reference power-source voltage line
LWN Lower electrode
M Metal line layer
MGL Metal gate line
ML Metal line
MLGB Branch reference power-source voltage line
MLGCM Main reference power-source voltage line
MLGCS Sub reference power-source voltage line
MLGP Reference power-source voltage line
MLGPM Pad side reference power-source voltage line
MLVB Branch power-source voltage line
MLVCM Main power-source voltage line
MLVCS Sub power-source voltage line
MLVP Power-source voltage line
MLVPM Pad side power-source voltage line
MN NMOS transistor
MP PMOS transistor
N Node
NS Power source noise
PD Pad
PERI Various peripheral circuits
PKG Package
PN External terminal
PSL Polysilicon layer
R, R′ Resistor
RAM Volatile memory
ROM Nonvolatile memory
RV Variable resistor
SC Silicide layer
STI Element-separation insulating film
SUB Semiconductor substrate
UPN Upper electrode
VCC Power source voltage
VDD Internal power source voltage
VREFG Reference voltage generating circuit
VREG Power-source voltage regulator circuit
VSS Reference power source voltage
Vref Reference voltage
WEL Well

What is claimed is:

1. A semiconductor device formed of one semiconductor substrate, comprising:
a first region for forming a core circuit block executing a predetermined process;
a first power-source voltage line disposed in the first region, the first power-source voltage line for supplying a first power source voltage to the core circuit block;
a first power-source voltage generating circuit for generating the first power source voltage using a power source voltage from outside;
a first power source pad disposed on the outside of the first region, the first power source pad for connecting an external capacitor;
a second power-source voltage line for connecting the first power source pad and the first power-source voltage line; and
an on-chip capacitor including a first electrode having a partial section of the second power-source voltage line and a second electrode for supplying a reference power source voltage,
wherein the first power source voltage on the first power-source voltage line is applied to the first power source pad through the first electrode.

2. The semiconductor device according to claim 1,
wherein the second power-source voltage line is disposed in a vicinity of the shortest route connecting the first region and the first power source pad.

3. The semiconductor device according to claim 2,
wherein the first power source voltage on the first power-source voltage line is applied to the first power source pad certainly through the first electrode.

4. The semiconductor device according to claim 3, further comprising a package for sealing the semiconductor substrate,
wherein the package includes a first power source terminal which is connected to the first power source pad.

5. The semiconductor device according to claim 4,
wherein a protection circuit for preventing electrostatic discharge damage is further connected to a node of the second power-source voltage line which is positioned between the first electrode and the first power source pad.

6. The semiconductor device according to claim 5,
wherein the on-chip capacitor is formed using a plurality of metal line layers on the semiconductor substrate, an inter-metal-line insulating film for isolating metal lines in the same metal line layer, and an interlayer insulating film for isolating metal lines in different metal line layers.

7. The semiconductor device according to claim 5,
wherein the on-chip capacitor includes:
a well formed in the semiconductor substrate and serving as the second electrode;
an insulating film formed on the well; and
a gate line formed on the insulating film and serving as the first electrode.

8. A semiconductor device formed of one semiconductor substrate, comprising:
a first region for forming a core circuit block executing a predetermined process;
a first power-source voltage line disposed in the first region, the first power-source voltage line for supplying a first power source voltage to the core circuit block;
a first power-source voltage generating circuit for generating the first power source voltage using a power source voltage from outside;
a first power source pad disposed on the outside of the first region, the first power source pad for connecting an external capacitor;
a second power-source voltage line for connecting the first power source pad and the first power-source voltage line; and
an on-chip capacitor including a first electrode having a partial section of the second power-source voltage line and a second electrode for supplying a reference power source voltage,
wherein the first and the second electrodes are formed of a plurality of metal line layers on the semiconductor substrate,
wherein the first electrode includes a plurality of first metal lines extending in a first direction next to each other between a first node and a second node serving as both ends of the partial section of the second power-source voltage line, and
wherein the second electrode includes a plurality of second metal lines extending in the first direction next to each other and disposed at a predetermined interval with respect to the plurality of first metal lines by interposing insulating films therebetween.

9. The semiconductor device according to claim 8,
wherein, when the plurality of first and second metal lines are viewed in a cross-sectional view perpendicular to the first direction, the first metal line and the second metal line are alternately disposed with insulating films interposed therebetween in the same layer as that of the plurality of metal line layers, and are alternately disposed with insulating films interposed therebetween in a layer direction of the plurality of metal line layers.

10. The semiconductor device according to claim 9,
wherein the on-chip capacitor is disposed in a vicinity of the shortest route connecting the first region and the first power source pad.

11. The semiconductor device according to claim 10,
wherein the first power source voltage on the first power-source voltage line is applied to the first power source pad certainly through the first electrode.

12. The semiconductor device according to claim 11,
wherein the first power-source voltage line includes:
a main power-source voltage line disposed along an outer peripheral portion of the first region; and
a sub power-source voltage line branched from the main power-source voltage line and disposed in a mesh shape,
wherein one end of the first electrode is connected to the main power-source voltage line, and
wherein the other end of the first electrode is connected to the first power source pad.

13. The semiconductor device according to claim 12, further comprising a package for sealing the semiconductor substrate,
wherein the package includes a first power source terminal which is connected to the first power source pad.

14. A semiconductor device formed of one semiconductor substrate, comprising:
a first region for forming a core circuit block executing a predetermined process;
a first power-source voltage line disposed in the first region, the first power-source voltage line for supplying a first power source voltage to the core circuit block;
a first power-source voltage generating circuit for generating the first power source voltage using a power source voltage from outside;
a first power source pad disposed on the outside of the first region, the first power source pad for connecting an external capacitor;
a second power-source voltage line for connecting the first power source pad and the first power-source voltage line; and
an on-chip capacitor including a first electrode having a partial section of the second power-source voltage line and a second electrode for supplying a reference power source voltage,
wherein the on-chip capacitor includes:
a well of a first conductive type formed in the semiconductor substrate;
a first semiconductor region of the first conductive type formed in the well and having an impurity concentration higher than that of the well;
an insulating film formed on the well;
a gate line formed on the insulating film; and
first and second contact layers, each of which is formed on both ends of the gate line,
wherein the gate line serves as the first electrode, and
wherein the well serves as the second electrode by supplying the reference power source voltage to the first semiconductor region.

15. The semiconductor device according to claim 14,
wherein the first power-source voltage line includes:
a main power-source voltage line disposed along an outer peripheral portion of the first region; and
a sub power-source voltage line branched from the main power-source voltage line and disposed in a mesh shape,
wherein the first contact layer is connected to the main power-source voltage line, and
wherein the second contact layer is connected to the first power source pad.

16. The semiconductor device according to claim 15,
wherein the first power source voltage on the first power-source voltage line is applied to the first power source pad certainly through the first electrode.

17. The semiconductor device according to claim 16,
wherein the first conductive type is an n-type.

18. The semiconductor device according to claim 17,
wherein the gate line is formed of a metal gate.

19. The semiconductor device according to claim 18, further comprising a package for sealing the semiconductor substrate,
wherein the package includes a first power source terminal which is connected to the first power source pad.
